(19) United States
(12) Patent Application Publication
(10) Pub. No.: US 2018/0352659 A1
(43) Pub. Date: Dec. 6, 2018

(54) THERMOSETTING MATERIAL USED FOR REINFORCING FLEXIBLE PRINTED CIRCUIT BOARD, REINFORCED FLEXIBLE PRINTED CIRCUIT BOARD, METHOD FOR PRODUCING THE REINFORCED FLEXIBLE PRINTED CIRCUIT BOARD, AND ELECTRONIC DEVICE

(71) Applicant: DIC Corporation, Tokyo (JP)

(72) Inventors: Koji Hayashi, Ichihara-shi (JP); Sumio Shimooka, Kitaadachi-gun (JP); Shota Tanii, Kitaadachi-gun (JP); Akinori Morino, Kitaadachi-gun (JP)

(73) Assignee: DIC Corporation, Tokyo (JP)

(21) Appl. No.: 15/778,006

(22) PCT Filed: Dec. 6, 2016
(86) PCT No.: PCT/JP2016/086162

§ 371 Date: May 22, 2018

(30) Foreign Application Priority Data
Dec. 11, 2015 (JP) 2015-242210
Dec. 11, 2015 (JP) 2015-242212

(51) Int. Cl. H05K 1/18; H05K 1/02; H05K 1/03

(52) U.S. Cl. CPC H05K 1/189; H05K 1/036; H05K 1/0271

(57) ABSTRACT

An object of the present invention is to provide a thermosetting material capable of forming a reinforcing member with which a flexible printed circuit board can be reinforced at a level high enough to prevent, for example, detachment of components even without using a reinforcing metal plate, which increases the thickness of an electronic device or the like. The present invention relates to a thermosetting material used for reinforcing a flexible printed circuit board. The thermosetting material has a modulus of tensile elasticity (×1) of 50 to 2,500 MPa at 25° C. A heat-cured product of the thermosetting material has a modulus of tensile elasticity (×2) of 2,500 MPa or more at 25° C.

### TECHNICAL FIELD

The present invention relates to a thermosetting material capable of forming a reinforcing member used for preventing, for example, detachment of components disposed on a flexible printed circuit board.

### BACKGROUND ART

With reductions in the sizes and thicknesses of portable electronic devices and the like, thin and bendable flexible printed circuit boards have been widely used as circuit boards included in such portable electronic devices and the like.

Known flexible printed circuit boards commonly include a ground circuit formed on the surface of a polyimide film or the like with copper or the like and components, such as connectors, disposed on a part of the circuit.

Most of the flexible printed circuit board are provided with a reinforcing metal plate, such as a stainless steel plate, bonded to a surface of the printed circuit board which is on a side opposite to the component side with an adhesive tape or the like in order to prevent poor connection between the circuit board and the components disposed thereon and detachment of the components from the circuit board which may occur due to a lapse of time (e.g., see PTL 1).

However, the use of the reinforcing plate inevitably increases the thickness of the flexible printed circuit board and the thickness of an electronic device that includes the flexible printed circuit board and may fail to meet a demand for reductions in the thicknesses of electronic devices and the like in the industrial community.

Bonding the flexible printed circuit board and the reinforcing plate to each other with an adhesive tape or the like requires the following two steps: a step in which the reinforcing plate and the adhesive tape are bonded to each other; and a step in which the reinforcing plate on which the adhesive tape is stuck is bonded to the flexible printed circuit board. Accordingly, shortening the time required for the above steps has been a challenge for the industrial community in order to enhance the efficiency with which reinforced flexible printed circuit boards, electronic devices, and the like are produced.

A method in which the ground circuit of a flexible printed circuit board and the other components are electrically connected to each other with a conductive adhesive tape in order to prevent noise from being generated due to the impact of electromagnetic wave is known (e.g., see PTL 1).

However, reducing the thickness of the conductive adhesive tape in order to reduce the thicknesses of the reinforced flexible printed circuit boards and electronic devices may degrade the followability of the conductive adhesive tape to stepped portions, such as an opening, formed in the flexible printed circuit board. The degradation in the followability of the conductive adhesive tape increases the likelihood of air bubbles remaining at the interface between the conductive adhesive tape and the flexible printed circuit board and, consequently, results in poor connection between the ground circuit and the components. Furthermore, the heat applied to the flexible printed circuit board when the components, such as connectors, are attached to the flexible printed circuit board causes the air bubbles to expand, which increases, for example, the likelihood of the components detaching from the flexible printed circuit board. Consequently, a good electromagnetic wave shielding property may fail to be achieved.

### CITATION LIST

### Patent Literature

PTL 1: International Publication No. 2014/132951

### SUMMARY OF INVENTION

### Technical Problem

An object of the present invention is to provide a thermosetting material capable of forming a reinforcing member with which a flexible printed circuit board can be reinforced at a level high enough to prevent, for example, detachment of the components even without using a reinforcing metal plate, which increases the thickness of an electronic device or the like.

Another object of the present invention is to provide a thermosetting material capable of markedly increasing the efficiency with which reinforced flexible printed circuit boards, electronic devices, and the like are produced.

Still another object of the present invention is to provide a thermosetting material capable of forming a reinforcing member having excellent followability to the stepped portions of a flexible printed circuit board.

Yet another object of the present invention is to provide a thermosetting material having excellent conductivity and an excellent adhesive property.

### Solution to Problem

The inventor of the present invention addressed the above issues by using a thermosetting material used for reinforcing a flexible printed circuit board, the thermosetting material having a modulus of tensile elasticity (×1) of 50 to 2,500 MPa at 25° C., a heat-cured product of the thermosetting material having a modulus of tensile elasticity (×2) of 2,500 MPa or more at 25° C.

### Advantageous Effects of Invention

The thermosetting material according to the present invention, which is a thermosetting reinforcing material capable of forming a reinforcing member with which the mechanical strength of a flexible printed circuit board can be increased to a level high enough to prevent, for example, detachment of the components even without using a reinforcing metal plate, which increases the thickness of an electronic device or the like, enables the thicknesses of reinforced flexible printed circuit boards, electronic devices, and the like to be markedly reduced.

The use of the thermosetting material according to the present invention, with which a flexible printed circuit board can be reinforced without using a reinforcing metal plate, eliminates the need to conduct the above-described two steps. This markedly increases the efficiency with which reinforced flexible printed circuit boards, electronic devices, and the like are produced.

The thermosetting material according to the present invention, which has excellent followability to the stepped portions of a flexible printed circuit board, reduces poor connection between the reinforcing member, which is a heat-cured product of the thermosetting material, and the flexible printed circuit board and enables an excellent electromagnetic wave shielding property to be achieved.

The thermosetting material according to the present invention, which has excellent conductivity and an excellent adhesive property, is suitably used for, for example, fixing a component of an electronic device in place.

### DESCRIPTION OF EMBODIMENTS

The thermosetting material according to the present invention has a modulus of tensile elasticity (×1) of 50 to 2,500 MPa at 25° C. The heat-cured product of the thermosetting material has a modulus of tensile elasticity (×2) of 2,500 MPa or more at 25° C. The thermosetting material according to the present invention is used primarily for reinforcing a flexible printed circuit board.

The thermosetting material has a modulus of tensile elasticity (×1) of 50 to 2,500 MPa at 25° C. before being cured by heat. Since the thermosetting material having a modulus of tensile elasticity (×1) that falls within the above range can be readily formed into a desired shape by punching, it can be readily formed into a shape that fits to the shape of a part of a flexible printed circuit board which needs to be reinforced. Furthermore, since such a thermosetting material is capable of readily following the shape of the surface of the part, it comes into intimate contact with the part and reinforces the part in a further effective manner. In addition, both an excellent adhesive property and an excellent conductivity can be achieved.

It is preferable to use a thermosetting material having a modulus of tensile elasticity (×1) of 50 to 1,000 MPa at 25° C., because, as described above, such a thermosetting material can be readily formed into a desired shape by punching and is capable of suitably following to the part that is to be reinforced while coming into intimate contact with the part. In addition, as described below, such a thermosetting material can be readily formed into a sheet-like shape, and is less likely to, for example, crack when wound in a roll. It is preferable to use a thermosetting material having a modulus of tensile elasticity (×1) of more than 1,000 MPa and less than 2,500 MPa at 25° C. in order to form a reinforcing member having a further high reinforcing property.

The thermosetting material is not any thermosetting material having a modulus of tensile elasticity (×1) that falls within the above range but a thermosetting material such that the heat-cured product thereof has a modulus of tensile elasticity (×2) of 2,500 MPa or more at 25° C. The use of the above-described thermosetting material makes it possible to achieve a certain level of stiffness with which a flexible printed circuit board can be supported and reinforced in a more effective manner even without using a reinforcing metal plate as in the related art.

The modulus of tensile elasticity (×2) of the heat-cured product of the thermosetting material at 25° C. is preferably 3,000 MPa or more and is more preferably 4,000 MPa or more in order to reinforce a flexible printed circuit board at a level sufficient for practical applications and reduce the thickness of the reinforced flexible printed circuit board. The upper limit for the modulus of tensile elasticity (×2) is not specified but is preferably 10,000 MPa or less and is more preferably 7,000 MPa or less.

The modulus of tensile elasticity (×2) is the modulus of tensile elasticity at 25° C. of a heat-cured product formed by heating the thermosetting material at 120° C. for 60 minutes.

The thermosetting material according to the present invention is preferably a conductive thermosetting material having a volume resistance of 0.1 to 50 mΩ·cm. The volume resistance of the thermosetting material is more preferably 0.1 to 20 mΩ·cm in order to make it possible to electrically connect a metal panel to a ground wire included in the reinforced flexible printed circuit board described below with a cushioning material, such as a conductive sponge, interposed between the metal panel and the ground wire when the reinforced flexible printed circuit board is attached to an electronic device and, consequently, effectively reduce the noise generated from the electronic device. Although the volume resistance of the heat-cured product of the thermosetting material may be the same or different from that of the thermosetting material that has not been cured by heat, it is more preferable that the volume resistance of the heat-cured product of the thermosetting material fall within the above preferable range in order to make it possible to electrically connect a metal panel to a ground wire included in the reinforced flexible printed circuit board described below with a cushioning material, such as a conductive sponge, interposed between the metal panel and the ground wire when the reinforced flexible printed circuit board is attached to an electronic device and, consequently, effectively reduce the noise generated from the electronic device.

The term “volume resistance” used herein refers to volume resistance measured with a resistance meter “Loresta-GP MCP-T600” (produced by Mitsubishi Chemical Corporation).

The thermosetting material according to the present invention may be a composition that includes the thermosetting resin described below and the like.

The thermosetting material is preferably provided in a sheet-like form (thermosetting thermal adhesive sheet), since the dimensions of a sheet-like thermosetting material are less likely to change during heat curing and a sheet-like thermosetting material is easy to handle.

The thickness of the sheet-like thermosetting material that has not been cured by heat is preferably 50 to 350 μm, is more preferably 100 to 350 μm, and is preferably 130 to 300 μm, because such a sheet-like thermosetting material is resistant to cracking and the like which may occur when the sheet-like thermosetting material is wound in a roll.

The thickness of the sheet-like thermosetting material that has been cured by heat is preferably 50 to 350 μm, is more preferably 80 to 300 μm, and is more preferably 100 to 300 μm, because the dimensions of such a sheet-like thermosetting material are less likely to change during heat curing and the sheet-like thermosetting material is easy to handle and has a certain level of stiffness with which a flexible printed circuit board can be strongly reinforced at a level high enough to prevent, for example, detachment of the components, even without using a reinforcing metal plate, which increases the thickness of an electronic device or the like.

The sheet-like thermosetting material is preferably a thermosetting material that becomes melted when being heated to about 100° C. or more and capable of bonding (joining) two or more adherends to one another.

The thermosetting material according to the present invention may be a composition that includes a thermosetting resin and, as needed, a conductive filler and the like. The composition may be formed into a desired shape.

Examples of the thermosetting resin include a compound (A) including two or more epoxy groups, a urethane resin, a phenolic resin, an unsaturated polyester resin, an acrylic resin. The thermosetting resin is preferably selected from the compound (A) including two or more epoxy groups, a urethane resin, and an acrylic resin, is preferably selected from the compound (A) including two or more epoxy groups and a urethane resin, and is particularly preferably the compound (A) including two or more epoxy groups in order to achieve a certain level of stiffness with which a flexible printed circuit board can be further strongly reinforced even when a reinforcing metal plate is not used as in the related art and the reinforcing member is thin, to increase the bonding strength of the thermosetting material to the surface of the ground circuit board and the polyimide film deposited on the surface of the flexible printed circuit board, and to reduce changes in dimensions which may occur during heat curing.

The amount of the compound (A) including two or more epoxy groups is preferably 80% by mass or more and is more preferably 90% by mass or more of the total amount of the thermosetting resins in order to reduce contraction due to heat curing and thereby reduce changes in dimensions which may occur during heat curing.

Using the compound (A) that is a compound including two or more epoxy groups enables an excellent adhesive property to be achieved. The compound (A) is preferably a compound including 2 to 3 epoxy groups per molecule on average in order to achieve an excellent adhesive property to metals, such as copper, and plastic films, such as a PET film and a polyimide film, to reduce changes in dimensions which may occur during curing, and to increase the stiffness of the cured product to a certain level at which an adherend, such as a flexible printed circuit board, can be further strongly reinforced.

The total epoxy equivalent weight of the compound (A) is preferably 300 to 2,000 g/eq. in order to effectively reduce the warpage of the cured product (reinforcing member) of the thermosetting material.

In particular, the compound (A) is preferably selected from an epoxy resin (a1) that is liquid at 23° C. and has an epoxy equivalent weight of 100 to 350 g/eq. and an epoxy resin (a2) that is solid at 23° C. and has an epoxy equivalent weight of 200 to 2,000 g/eq. It is more preferable to use the epoxy resins (a1) and (a2) in combination with each other in order to achieve both an excellent stiffness and an excellent adhesive property.

An epoxy resin preferably having an epoxy equivalent weight of 2000 g/eq. or more and preferably having an epoxy equivalent weight of more than 2000 g/eq. and 15000 g/eq. or less may be used in combination with the epoxy resins (a1) and (a2) above. In such a case, the flexibility and toughness of the thermosetting material are suitably enhanced to certain degrees required when the thermosetting material is formed into a sheet-like shape.

The compound (A) may be a compound that includes two or more epoxy groups per molecule. Specific examples of the compound (A) include epoxy resins, such as a bisphenol epoxy resin (e.g., a bisphenol-A epoxy resin or a bisphenol-F epoxy resin), a biphenyl epoxy resin, a tetramethylbiphenyl epoxy resin, a polyhydroxynaphthalene epoxy resin, an isocyanate-modified epoxy resin, a 10-(2,5-dihydroxyphenyl)-9,10-dihydro 9-oxa-10-phosphaphenanthrene-10-oxide-modified epoxy resin, a phenol novolac epoxy resin, a cresol novolac epoxy resin, a triphenylmethane epoxy resin, a tetraphenylethane epoxy resin, a dicyclopentadiene-phenol addition reaction epoxy resin, a phenol aralkyl epoxy resin, a naphthol novolac epoxy resin, a naphthol aralkyl epoxy resin, a naphthol-phenol co-condensation novolac epoxy resin, a naphthol-cresol co-condensation novolac epoxy resin, an aromatic hydrocarbon formaldehyde resin-modified phenolic resin epoxy resin, a biphenyl-modified novolac epoxy resin, a 1,6-dihydroxynaphthalene epoxy resin, a t-butylcatechol epoxy resin, a 4,4′-diphenyldiaminomethane epoxy resin, and a p- or m-aminophenol epoxy resin; acrylic resins including an epoxy group; and urethane resins including an epoxy group.

The compound (A) including two or more epoxy groups is preferably an epoxy resin. More preferably, the epoxy resin is selected from a bisphenol epoxy resin, such as a bisphenol-A epoxy resin or a bisphenol-F epoxy resin, a polyhydroxynaphthalene epoxy resin, an isocyanate-modified epoxy resin, a 10-(2,5-dihydroxyphenyl)-9,10-dihydro 9-oxa-10-phosphaphenanthrene-10-oxide-modified epoxy resin, and a dicyclopentadiene-phenol addition reaction epoxy resin in order to produce a thermosetting material having a modulus of tensile elasticity (×1) and a modulus of tensile elasticity (×2) that fall within the respective predetermined ranges described above, to thereby form a reinforcing member with which a flexible printed circuit board can be reinforced at a level high enough to prevent, for example, detachment of the components, even without using a reinforcing metal plate, which increases the thickness of an electronic device or the like, which markedly enhances the efficiency with which reinforced flexible printed circuit boards, electronic devices, and the like are produced, and to form a reinforcing member having excellent followability to the stepped portions of a flexible printed circuit board.

Examples of the epoxy resin (a1) include bisphenol epoxy resins, such as a bisphenol-A epoxy resin and a bisphenol-F epoxy resin, a 1,6-dihydroxynaphthalene epoxy resin, a t-butylcatechol epoxy resin, a 4,4′-diphenyldiaminomethane epoxy resin, and a p- or m-aminophenol epoxy resin.

Examples of the epoxy resin (a2) include an epoxy resin produced by reacting a bisphenol epoxy resin with a bisphenol compound, a dicyclopentadiene epoxy resin, such as a dicyclopentadiene-phenol addition reaction epoxy resin, a polyhydroxynaphthalene epoxy resin, an isocyanate-modified bisphenol epoxy resin, a 10-(2,5-dihydroxyphenyl)-9,10-dihydro 9-oxa-10-phosphaphenanthrene-10-oxide-modified epoxy resin, a copolymer of 2-methoxynaphthalene with an orthocresol novolac epoxy resin, a biphenylene phenol aralkyl resin, and a phenol aralkyl resin. Among the above epoxy resins, in particular, a dicyclopentadiene epoxy resin, such as a dicyclopentadiene-phenol addition reaction epoxy resin, an isocyanate-modified bisphenol epoxy resin, and a 10-(2,5-dihydroxyphenyl)-9,10-dihydro 9-oxa-10-phosphaphenanthrene-10-oxide-modified epoxy resin are preferably used in order to achieve both an excellent stiffness and an excellent adhesive property.

The thermosetting material according to the present invention may optionally include constituents other than the thermosetting resin. The thermosetting material preferably includes the thermosetting resin and a conductive filler (B) in order to form a reinforcing member having an excellent conductivity.

The conductive filler (B) may be selected from known conducting substances, such as particles of a metal, such as gold, silver, copper, nickel, stainless steel, or aluminum, particles of a conductive resin, such as carbon or graphite, or particles prepared by coating the surfaces of resin particles, solid-core glass beads, or hollow-core glass beads with a metal.

Among the above conductive fillers (B), particles of nickel or copper are preferably used. It is particularly preferable to use a nickel powder produced by the carbonyl process or a copper powder produced by an electrolytic process in order to form a reinforcing member having a further high conductivity.

Specifically, for example, nickel powders NI255 and NI287 (produced by Inco Limited) produced by the carbonyl process and a copper powder FCC-115 (produced by Fukuda Metal Foil & Powder Co., Ltd.) produced by an electrolytic process are suitably used as a conductive filler (B).

It is more preferable to use, as a conductive filler (B), particles of stainless steel and the particles of nickel or copper described above in combination with each other and is particularly preferable to use particles of stainless steel and the particles of nickel described above in combination with each other in order to effectively reduce the formation of an oxide layer on the surfaces of the conductive filler particles due to heat, which reduces conductivity, and to reduce the production costs of the thermosetting material.

The conductive filler (B) preferably includes the acicular or scale-like conductive filler particles (b1) and substantially spherical conductive filler particles (b2). It is more preferable to use the above conductive filler particles such that the volume ratio [(b1)/(b2)] of the conductive filler particles (b1) to the conductive filler particles (b2) is 1/1 to 4/1. It is preferable to use the above conductive filler particles such that the volume ratio [(b1)/(b2)] is 1.5/1 to 3/1 in order to produce a thermosetting material having an excellent conductivity and an excellent adhesive property. The above thermosetting material is easy to handle and has excellent workability since the flow of the adhesive constituents, such as the compound (A) including two or more epoxy groups, which may occur when the thermosetting material is cured by heat can be reduced.

Examples of the acicular or scale-like conductive filler particles (b1) include particles of a metal, such as gold, silver, copper, nickel, stainless steel, or aluminum, carbon, graphite, and particles produced by coating the surfaces of acicular or scale-like resin particles, glass flakes, or the like with a metal. Among the above conductive filler particles, in particular, nickel and copper are preferably used. It is more preferable to use acicular nickel particles produced by the carbonyl process in order to further enhance conductivity. Specifically, for example, nickel powders NI255 and NI287 (produced by Inco Limited), which are produced by the carbonyl process, are suitably used as conductive filler particles (b1).

The conductive filler particles (b1) preferably have an acicular or scale-like shape having an average aspect ratio of more than 3.

The 50% average volume particle size of the conductive filler (b1) is preferably 0.1 to 200 μm, is more preferably 1 to 100 μm, is further preferably 15 to 50 μm, and is particularly preferably 15 to 40 μm in order to enhance the dispersibility of the conductive filler (b1) in the resin composition included in the thermosetting material according to the present invention and to readily apply the composition in a sheet-like form. The 50% volume particle size of the conductive filler (b1) is measured with a laser diffraction particle size analyzer SALD-3000 produced by Shimadzu Corporation in which isopropanol is used as a dispersion medium.

The “longer-axis average length L”, “shorter-axis average length d”, and “average thickness T” of the conductive filler (B), which are used for the calculation of aspect ratio (L/t), are determined by observing an SEM image of the conductive filler (B) taken with a scanning electron microscope (SEM). The measurement of “longer-axis average length L” and “shorter-axis average length d” is made by the following method. A line segment having the maximum length is considered to be the longer axis, and the length of the line segment is measured as “longer-axis length” L. A portion that includes the longer axis and has a shape close to a rectangle is considered to be a principal part. The maximum length d of the particle in a direction perpendicular to the longer axis is measured as “shorter-axis length”. The aspect ratio of the particle is determined by calculating the ratio therebetween. In the case where the particle has a portion (branch) protruded from the principal portion in a direction different from the direction of the principal portion, the length of the longer axis, which is the longest, is referred to as L, the portion that corresponds to the width of the longer axis is considered to be the shorter axis d.

The substantially spherical conductive filler particles (b2) are preferably particles of stainless steel, nickel, or the like in order to effectively reduce the formation of an oxide layer on the surfaces of the conductive filler particles (b2) due to heat, which reduces conductivity, and to reduce the production costs of the thermosetting material.

The conductive filler particles (b2) may have a spherical shape or an elliptical shape. The average aspect ratio of the conductive filler particles (b2) is preferably less than 2.

The 50% average volume particle size of the conductive filler particles (b2) is preferably 0.1 to 200 μm, is more preferably 1 to 100 μm, is further preferably 15 to 50 μm, and is particularly preferably 15 to 40 μm in order to enhance the dispersibility of the conductive filler (b2) in the resin composition included in the thermosetting material according to the present invention and to readily apply the composition in a sheet-like form. The 50% volume particle size of the conductive filler is measured with a laser diffraction particle size analyzer SALD-3000 produced by Shimadzu Corporation in which isopropanol is used as a dispersion medium.

The apparent density of the conductive filler (B) is preferably 5.0 g/cm³ or less, is more preferably 4.5 g/cm³ or less, and is particularly preferably 4.0 g/cm³ or less in order to reduce the likelihood of particles of the conductive filler (B) settling in the resin composition included in the thermosetting material according to the present invention and to maintain the particles of the conductive filler (B) to be dispersed in a relatively uniform manner for a few hours. The apparent density of the conductive filler (B) is measured in accordance with JIS Z2504-2000 “Metallic powders-Determination of apparent density.

The conductive filler (B) may be a conductive filler that has been subjected to a surface treatment using a titanate coupling agent, an aluminate coupling agent, or the like in order to further enhance the dispersibility of the conductive filler in the resin composition included in the thermosetting material according to the present invention and to produce a reinforcing member having an excellent electrical conductivity with consistency.

The ratio of the volume of the conductive filler (B) to the total volume of the compound (A) and the conductive filler (B) is preferably 10% to 50% by volume, is more preferably 10% to 30% by volume, and is further preferably 20% to 30% by volume. When the amount of conductive filler used is increased, in general, an excellent conductivity is achieved, but an adhesive property may become significantly degraded. However, the resin composition included in the thermosetting material according to the present invention is capable of maintaining an excellent adhesive property even when the amount of conductive filler (B) used is increased. The thermosetting material that is a conductive adhesive sheet produced using the resin composition is easy to handle and has excellent workability since the flow of the adhesive constituents, such as the compound (A) including two or more epoxy groups, which may occur when the thermosetting material is cured by heat can be reduced.

The amount of conductive filler used is preferably 50 to 1,000 parts by mass and is more preferably 100 to 500 parts by mass relative to 100 parts by mass of the thermosetting resin (solid content) in order to produce a thermosetting material capable of forming a reinforcing member having adhesion and an excellent conductivity.

The thermosetting material may further include constituents other than the conductive filler (B). Examples of the other constituents include electrically insulative fillers, such as aluminum hydroxide, aluminum oxide, aluminum nitride, magnesium hydroxide, magnesium oxide, mica, talc, boron nitride, and glass flakes.

The thermosetting material preferably includes a curing agent capable of reacting with the thermosetting resin.

In the case where the thermosetting resin is an epoxy resin, the curing agent preferably includes a functional group capable of reacting with an epoxy group.

Examples of the curing agent include an amine compound, an amide compound, an acid anhydride, and a phenolic compound. Examples of the amine compound include diaminodiphenylmethane, diethylenetriamine, triethylenetetramine, diaminodiphenylsulfone, isophoronediamine, an imidazole derivative, a BF3-amine complex, and a guanidine derivative.

Examples of the amide compound include dicyandiamide and a polyamide resin synthesized from linoleic acid dimer and ethylenediamine. Examples of the acid anhydride compound include phthalic anhydride, trimellitic anhydride, pyromellitic anhydride, maleic anhydride, tetrahydrophthalic anhydride, methyltetrahydrophthalic anhydride, methylnadic anhydride, hexahydrophthalic anhydride, and methylhexahydrophthalic anhydride. Examples of the phenolic compound include the following polyhydric phenolic compounds: a phenol novolac resin, a cresol novolac resin, an aromatic hydrocarbon formaldehyde resin-modified phenolic resin, a dicyclopentadiene phenol addition-type resin, a phenol aralkyl resin (Xylok resin), a naphthol aralkyl resin, a trimethylolmethane resin, a tetraphenylolethane resin, a naphthol novolac resin, a naphthol-phenol co-condensed novolac resin, a naphthol-cresol co-condensed novolac resin, a biphenyl-modified phenolic resin (polyhydric phenolic compound including phenol nuclei connected with a bismethylene group), a biphenyl-modified naphthol resin (polyhydric naphthol compound including phenol nuclei connected with a bismethylene group), an aminotriazine-modified phenolic resin (a compound having a molecular structure including a phenol skeleton, a triazine ring, and a primary amino group), and an alkoxy group-containing aromatic ring-modified novolac resin (a polyhydric phenolic compound including a phenol nucleus and an alkoxy group-containing aromatic ring connected with formaldehyde).

The amount of the curing agent used is preferably 1 to 60 parts by mass and is preferably 5 to 30 parts by mass relative to 100 parts by mass of all the thermosetting resins, such as the epoxy resin.

The thermosetting material may optionally include a curing accelerator. Examples of the curing accelerator include a phosphorus-based compound, an amine compound, and an imidazole derivative. In the case where the curing accelerator is used, the amount of curing accelerator is preferably 0.1 to 5 parts by mass and is more preferably 0.5 to 3 parts by mass relative to 100 parts by mass of all the thermosetting resins, such as the epoxy resin.

The curing agent and the curing accelerator are preferably provided in powder form. Using a powdery curing accelerator, which is more likely to suppress a thermosetting reaction at low temperatures than liquid curing accelerators, further enhances the stability with which the thermosetting material that has not been cured by heat is stored at room temperatures.

The thermosetting material may optionally include a thermoplastic resin in order to enhance the toughness of the reinforcing member, that is, the heat-cured product of the thermosetting material, to a level high enough to prevent, for example, chipping of the reinforcing member even under the condition where temperature changes are significant.

Examples of the thermoplastic resin include a thermoplastic polyester resin and a thermoplastic urethane resin. In particular, a thermoplastic polyester resin is preferably used. It is preferable to use a polyether ester amide resin or a polyvinyl acetoacetal resin in order to reduce the flow of thermosetting material according to the present invention which may occur when the thermosetting material is cured by heat and to produce a thermosetting material capable of forming a reinforcing member having the certain level of brittleness described above and a certain level of stiffness with which a flexible printed circuit board can be sufficiently reinforced.

For the above reasons, the amount of the thermoplastic resin used is preferably 1 to 100 parts by mass, is more preferably 5 to 100 parts by mass, and is particularly preferably 5 to 40 parts by mass relative to 100 parts by mass of the thermosetting resin.

As described above, the thermosetting material may be formed into any shape, such as a sheet-like shape, before use. In order to enhance the efficiency with which the composition including the thermosetting resin and the like is formed into the sheet-like shape or the like, the composition preferably includes a solvent in addition to the thermosetting resin, the conductive filler (B), the curing agent, and the like.

Examples of the solvent include ester solvents, such as methyl acetate, ethyl acetate, propyl acetate, and butyl acetate; ketone solvents, such as acetone, methyl kethyl ketone, methyl isobutyl ketone, diisobutyl ketone, and cyclohexanone; and aromatic hydrocarbon solvents, such as toluene and xylene.

The thermosetting material may further include the following additives such that the advantageous effects of the present invention are not impaired: a filler, a softener, a stabilizer, an adhesion promoter, a leveling agent, an antifoaming agent, a plasticizer, a tackifier resin, fibers, an antioxidant, an ultraviolet absorber, an antihydrolysis agent, a thickener, a colorant (e.g., a pigment), and a filler.

The thermosetting material according to the present invention is produced by mixing the thermosetting resin with the optional constituents, such as the conductive filler (B), the curing agent, and the solvent.

For mixing the above constituents to produce the thermosetting material, a dissolver, a butterfly mixer, a BDM twin shaft mixer, a planetary mixer, and the like may be used as needed. It is preferable to use a dissolver or a butterfly mixer. In the case where the conductive filler is used, it is preferable to use a planetary mixer in order to enhance the dispersibility of the conductive filler.

The curing agent and the curing accelerator are preferably used before the thermosetting material is cured by heat or before the thermosetting material is formed into a sheet-like shape or the like.

The sheet-like thermosetting material is an adhesive sheet and produced by, for example, preparing a composition including the thermosetting resin and the optional constituents, such as the conductive filler (B), the curing agent, and the solvent, applying the composition to the surface of a release liner or the like, and drying the composition deposited on the release liner.

The drying is preferably performed at about 50° C. to 120° C. and is more preferably performed at about 50° C. to 90° C. in order to inhibit the thermosetting reaction of the thermosetting material.

The conductive adhesive sheet may be sandwiched between the release liners until it is stuck to an adherend, such as a flexible printed circuit board.

Examples of the release liner include a sheet of paper, such as kraft paper, glassine paper, or wood free paper; a resin film, such as a polyethylene film, a polypropylene (OPP or CPP) film, or a polyethylene terephthalate film; a laminated paper including the above paper sheet and a resin film deposited on the paper sheet; and a paper sheet produced by filling the above paper sheet with clay, polyvinyl alcohol, or the like and subjecting one or both of the surfaces of the paper sheet to a release treatment using a silicone resin or the like.

The thermosetting material according to the present invention which is prepared by the above method can be used primarily as a material for a reinforcing member of a flexible printed circuit board, since the thermosetting material that has not been cured is relatively flexible and has excellent followability to the stepped portions of an adherend and the thermosetting material considerably hardens and is capable of reinforcing the adherend to a sufficient degree after being cured by heat.

The thickness of the adhesive sheet, that is, the sheet-like thermosetting material, that has not been cured by heat is preferably 50 to 350 μm, is more preferably 100 to 350 μm, and is preferably 115 to 300 μm in order to reduce the likelihood of cracking and the like occurring when the adhesive sheet is wound in a roll.

The thickness of the adhesive sheet that has been cured by heat is preferably 50 to 350 μm, is more preferably 80 to 300 μm, and is more preferably 100 to 350 μm in order to reduce changes in dimensions which may occur during heat curing, to increase ease of handling, and to achieve a certain level of stiffness with which a flexible printed circuit board can be strongly reinforced at a level high enough to prevent, for example, detachment of the components, even without using a reinforcing metal plate, which increases the thickness of an electronic device or the like.

The adhesive sheet may be a sheet-like material that is substantially not tacky at room temperatures. The adhesive sheet is preferably an adhesive sheet that becomes melted and capable of bonding (joining) two or more adherends to one another when heated to about 100° C. or more.

A reinforced flexible printed circuit board that includes a flexible printed circuit board and a reinforcing member deposited thereon is primarily used as a flexible printed circuit board. Although stainless steel sheets have been used as a reinforcing member, in the present invention, the heat-cured product of the thermosetting material can be used alone as a reinforcing member. This enables both a reduction in the thickness of a flexible printed circuit board and excellent followability to the stepped portions of a flexible printed circuit board, such as an opening.

The modulus of tensile elasticity (×3) of the reinforcing member at 25° C. is preferably 2,500 MPa or more, is more preferably 3,000 MPa or more, and is particularly preferably 4,000 to 20,000 MPa in order to strongly reinforce a flexible printed circuit board without using the stainless steel sheet or the like.

The reinforcing member can be formed by, for example, curing the thermosetting material preferably at 120° C. or more and more preferably at 120° C. to 200° C. for 5 to 120 minutes.

A flexible printed circuit board provided with the reinforcing member is commonly referred to as “reinforced flexible printed circuit board” and included in an electronic device.

The reinforced flexible printed circuit board can be produced by, for example, a step [1] in which the thermosetting material is stuck or applied to a surface of a flexible printed circuit board which is on a side opposite to the component side of the flexible printed circuit board, and a step [2] in which the thermosetting material is heated to 120° C. or more so as to be cured by heat and form a reinforcing member.

Although the attachment of components to the flexible printed circuit board may be done prior to the step [1], it is preferably done subsequent to the steps [1] and [2] in order to effectively prevent poor connection of the components from occurring in the mounting step.

The reinforced flexible printed circuit board is included primarily in portable electronic devices, such as smart phones, and electronic devices, such as computers. In such cases, the reinforced flexible printed circuit board is preferably attached to the electronic device with a cushioning material being deposited directly on the flexible printed circuit board and the surface of the reinforcing member included in the reinforced flexible printed circuit board. Alternatively, another layer may be interposed between the cushioning material and the flexible printed circuit board or the surface of the reinforcing member.

The cushioning material deposited may be bonded to the flexible printed circuit board and the surface of the reinforcing member or the other layer either with or without an adhesive or the like.

Examples of the cushioning material include a urethane foam, a polyethylene foam, and a silicon sponge. It is preferable to use a conductive urethane foam.

The thickness of the cushioning material is about 0.1 to 5.0 mm.

An electronic device including the cushioning material is capable of effectively reducing occurrence of malfunction resulting from noise.

### EXAMPLES

Examples and Comparative examples are specifically described below.

### Example 1

A thermosetting resin composition (X-1) was prepared by mixing 200 parts by mass of a methyl ethyl ketone solution (solid content: 30 mass %) of JER-1256 (produced by Mitsubishi Chemical Corporation, bisphenol-A epoxy resin, epoxy equivalent weight: 8,000 g/eq.), 10 parts by mass of 850-S (produced by DIC Corporation, bisphenol-A epoxy resin, epoxy equivalent weight: 188 g/eq.), 42.9 parts by mass of a methyl ethyl ketone solution (solid content: 70 mass %) of HP-7200HHH (produced by DIC Corporation, dicyclopentadiene epoxy resin, epoxy equivalent weight: 285 g/eq.), and 2.0 parts by mass of 2MAOK-PW (produced by Shikoku Chemicals Corporation, 2,4-diamino-6-[2′-methylimidazolyl-(1′)]-ethyl-s-triazine isocyanuric acid adduct).

As an inorganic filler (C), 217.3 parts by mass of NI-255 (nickel powder produced by Inco Limited, 50% average particle size: 21 μm, apparent density: 0.6 g/cm³, acicular) relative to 100 parts by mass of the solid content of the thermosetting resins included in the thermosetting resin composition (X-1) and 96.8 parts by mass of DAP-316L-HTD (stainless steel powder produced by Daido Steel Co., Ltd., 50% average particle size: 10.7 μm, apparent density: 4.1 g/cm³, roundish) relative to 100 parts by mass of the solid content of the thermosetting resins were mixed with the thermosetting resin composition (X-1). The resulting mixture was stirred with a dispersion stirrer for 10 minutes to form a conductive thermosetting resin composition (Y-1).

The conductive thermosetting resin composition (Y-1) was applied onto the surface of a release liner (polyethylene terephthalate film having a thickness of 50 μm one surface of which had been made releasable using a silicone compound) with a rod-like metal applicator such that the resulting coating film had a thickness of 140 μm after being dried.

The release liner on which the conductive thermosetting resin composition (Y-1) was deposited was charged in a dryer for 5 minutes at 85° C. and dried. Hereby, a sheet-like conductive thermosetting reinforcing material (Z-1) having a thickness of 140 μm was prepared.

### Example 2

A conductive thermosetting resin composition (Y-2) and a sheet-like conductive thermosetting reinforcing material (Z-2) having a thickness of 140 μm were prepared as in Example 1, except that 2.0 parts by mass of DICY-7 (produced by Mitsubishi Chemical Corporation, dicyandiamide) was used instead of 2MAOK-PW.

### Example 3

A conductive thermosetting resin composition (Y-3) and a sheet-like conductive thermosetting reinforcing material (Z-3) having a thickness of 140 μm were prepared as in Example 1, except that the amount of the methyl ethyl ketone solution (solid content: 30 mass %) of JER-1256 (produced by Mitsubishi Chemical Corporation, bisphenol-A epoxy resin) was changed from 200 parts by mass to 100 parts by mass, and 150 parts by mass of a toluene-isopropanol solution (solid content: 20 mass %) of PA-201 (produced by T&K TOKA, polyether ester amide resin) was further used.

### Example 4

A conductive thermosetting resin composition (Y-4) and a conductive thermosetting reinforcing material (Z-4) having a thickness of 140 μm were prepared as in Example 1, except that 10 parts by mass of 830-S (produced by DIC Corporation, bisphenol-F epoxy resin, epoxy equivalent weight: 170 g/eq.) was used instead of 850-S (produced by DIC Corporation, bisphenol-A epoxy resin, epoxy equivalent weight: 188 g/eq.), 50 parts by mass of a methyl ethyl ketone solution (solid content: 80 mass %) of TSR-400 (produced by DIC Corporation, isocyanate modified bisphenol-A epoxy resin, epoxy equivalent weight: 343 g/eq.) was used instead of the methyl ethyl ketone solution (solid content: 70 mass %) of HP-7200HHH (produced by DIC Corporation, dicyclopentadiene epoxy resin, epoxy equivalent weight: 285 g/eq.), the amount of the methyl ethyl ketone solution (solid content: 30 mass %) of JER-1256 (produced by Mitsubishi Chemical Corporation, bisphenol-A epoxy resin) was changed from 200 parts by mass to 166.7 parts by mass, and the amount of the 2MAOK-PW (produced by Shikoku Chemicals Corporation, 2,4-diamino-6-[2′-methylimidazolyl-(1′)]-ethyl-s-triazine isocyanuric acid adduct) used was changed from 2 parts by mass to 1 part by mass.

### Example 5

A conductive thermosetting resin composition (Y-5) and a conductive thermosetting reinforcing material (Z-5) having a thickness of 140 μm were prepared as in Example 1, except that 20 parts by mass of 830-S (produced by DIC Corporation, bisphenol-F epoxy resin, epoxy equivalent weight: 170 g/eq.) was used instead of 850-S (produced by DIC Corporation, bisphenol-A epoxy resin, epoxy equivalent weight: 188 g/eq.), 30 parts by mass of 1055 (produced by DIC Corporation, bisphenol-A epoxy resin, epoxy equivalent weight: 475 g/eq.) was used instead of the methyl ethyl ketone solution (solid content: 70 mass %) of HP-7200HHH (produced by DIC Corporation, dicyclopentadiene epoxy resin, epoxy equivalent weight: 285 g/eq.), the amount of the methyl ethyl ketone solution (solid content: 30 mass %) of JER-1256 (produced by Mitsubishi Chemical Corporation, bisphenol-A epoxy resin) used was changed from 200 parts by mass to 150 parts by mass, and 5 parts by mass of S-LEC KS-1 (produced by SEKISUI CHEMICAL CO., LTD., polyvinyl acetal resin) and 1.5 parts by mass of DN-980 (produced by DIC Corporation, polyisocyanate curing agent) were further used.

### Example 6

A conductive thermosetting resin composition (Y-6) and a conductive thermosetting reinforcing material (Z-6) having a thickness of 140 μm were prepared as in Example 5, except that the amount of NI-255 (nickel powder produced by Inco Limited, 50% average particle size: 21 μm, apparent density: 0.6 g/cm³) used was changed from 217.3 parts by mass to 168 parts by mass, and the amount of DAP-316L-HTD (stainless steel powder produced by Daido Steel Co., Ltd., 50% average particle size: 10.7 μm, apparent density: 4.1 g/cm³) used was changed from 96.8 parts by mass to 75.2 parts by mass.

### Example 7

A conductive thermosetting resin composition (Y-7) and a conductive thermosetting reinforcing material (Z-7) having a thickness of 140 μm were prepared as in Example 5, except that the amount of NI-255 (nickel powder produced by Inco Limited, 50% average particle size: 21 μm, apparent density: 0.6 g/cm³) used was changed from 217.3 parts by mass to 271.3 parts by mass, and the amount of DAP-316L-HTD (stainless steel powder produced by Daido Steel Co., Ltd., 50% average particle size: 10.7 μm, apparent density: 4.1 g/cm³) used was changed from 96.8 parts by mass to 121.5 parts by mass.

### Example 8

A conductive thermosetting resin composition (Y-8) and a conductive thermosetting reinforcing material (Z-8) having a thickness of 140 μm were prepared as in Example 5, except that the amount of NI-255 (nickel powder produced by Inco Limited, 50% average particle size: 21 μm, apparent density: 0.6 g/cm³) used was changed from 217.3 parts by mass to 162 parts by mass, and the amount of DAP-316L-HTD (stainless steel powder produced by Daido Steel Co., Ltd., 50% average particle size: 10.7 μm, apparent density: 4.1 g/cm³) used was changed from 96.8 parts by mass to 145.1 parts by mass.

### Example 9

A conductive thermosetting resin composition (Y-9) and a conductive thermosetting reinforcing material (Z-9) having a thickness of 140 μm were prepared as in Example 5, except that the amount of NI-255 (nickel powder produced by Inco Limited, 50% average particle size: 21 μm, apparent density: 0.6 g/cm³) used was changed from 217.3 parts by mass to 243 parts by mass, and the amount of DAP-316L-HTD (stainless steel powder produced by Daido Steel Co., Ltd., 50% average particle size: 10.7 μm, apparent density: 4.1 g/cm³) used was changed from 96.8 parts by mass to 72.5 parts by mass.

### Example 10

A conductive thermosetting resin composition (Y-10) and a conductive thermosetting reinforcing material (Z-10) having a thickness of 140 μm were prepared as in Example 5, except that the amount of NI-255 (nickel powder produced by Inco Limited, 50% average particle size: 21 μm, apparent density: 0.6 g/cm³) used was changed from 217.3 parts by mass to 259 parts by mass, and the amount of DAP-316L-HTD (stainless steel powder produced by Daido Steel Co., Ltd., 50% average particle size: 10.7 μm, apparent density: 4.1 g/cm³) used was changed from 96.8 parts by mass to 58 parts by mass.

### Example 11

A conductive thermosetting reinforcing material (Z-11) was prepared as in Example 5, except that the thickness of the thermally conductive thermosetting adhesive sheet was changed from 140 μm to 160 μm.

### Example 12

A conductive thermosetting reinforcing material (Z-12) was prepared as in Example 5, except that the thickness of the thermally conductive thermosetting adhesive sheet was changed from 140 μm to 110 μm.

### Example 13

A conductive thermosetting reinforcing material (Z-13) was prepared as in Example 5, except that the thickness of the thermally conductive thermosetting adhesive sheet was changed from 140 μm to 90 μm.

### Example 14

A conductive thermosetting resin composition (Y-14) and a conductive thermosetting reinforcing material (Z-14) having a thickness of 140 μm were prepared as in Example 1, except that the amount of 850-S (produced by DIC Corporation, bisphenol-A epoxy resin, epoxy equivalent weight: 188 g/eq.) used was changed from 10 parts by mass to 0 part by mass, 71.6 parts by mass of polyurethane (hydrogenated MDI/PTMG prepolymer, isocyanate-group equivalent weight: 310), which is produced by reacting hydrogenated 4,4′-diphenylmethane diisocyanate with polyoxytetramethylene glycol, was used instead of the methyl ethyl ketone solution (solid content: 70 mass %) of HP-7200HHH (produced by DIC Corporation, dicyclopentadiene epoxy resin, epoxy equivalent weight: 285 g/eq.), 28.4 parts by mass of dichlorodiaminodiphenylmethane (MBOCA) was used instead of the methyl ethyl ketone solution (solid content: 30 mass %) of JER-1256 (produced by Mitsubishi Chemical Corporation, bisphenol-A epoxy resin), and the amount of 2MAOK-PW used was changed from 2 part by mass to 0 part by mass.

### Example 15

A conductive thermosetting resin composition (Y-15) and a thermosetting reinforcing material (Z-15) that was a conductive adhesive sheet having a thickness of 140 μm were prepared as in Example 2, except that 42.9 parts by mass of a methyl ethyl ketone solution (solid content: 70 mass %) of HP7200 (produced by DIC Corporation, dicyclopentadiene epoxy resin, epoxy equivalent weight: 260 g/eq.) was used instead of the methyl ethyl ketone solution (solid content: 70 mass %) of HP7200HHH (produced by DIC Corporation, dicyclopentadiene epoxy resin, epoxy equivalent weight: 285 g/eq.), the amount of methyl ethyl ketone solution (solid content: 30 mass %) of JER-1256 (produced by Mitsubishi Chemical Corporation, bisphenol-A epoxy resin) used was changed from 200 parts by mass to 133.3 parts by mass, 10 parts by mass of 830-S (produced by DIC Corporation, bisphenol-F epoxy resin, epoxy equivalent weight: 170 g/eq.) was used instead of 850-S (produced by DIC Corporation, bisphenol-A epoxy resin, epoxy equivalent weight: 188 g/eq.), and 28.6 parts by mass of a methyl ethyl ketone solution (solid content: 70 mass %) of EXA-9726 (produced by DIC Corporation, phosphorus-modified epoxy resin, epoxy equivalent weight: 475 g/eq.) was further used.

### Example 16

A conductive thermosetting resin composition (Y-16) and a thermosetting reinforcing material (Z-16) that was a conductive adhesive sheet having a thickness of 140 μm were prepared as in Example 4, except that 0.9 parts by mass of 2MAOK (produced by Shikoku Chemicals Corporation, 2,4-diamino-6-[2′-methylimidazolyl-(1′)]-ethyl-s-triazine isocyanuric acid adduct) was used instead of 2MAOK-PW (produced by Shikoku Chemicals Corporation, 2,4-diamino-6-[2′-methylimidazolyl-(1′)]-ethyl-s-triazine isocyanuric acid adduct), and 1.5 parts by mass of DICY-7 (produced by Mitsubishi Chemical Corporation, dicyandiamide) and 5.4 parts by mass of 4,4′-diaminodiphenyl suMAlfone were further used.

### Example 17

A conductive thermosetting resin composition (Y-17) and a thermosetting reinforcing material (Z-17) that was a conductive adhesive sheet having a thickness of 140 μm were prepared as in Example 4, except that the amount of NI-255 (nickel powder produced by Inco Limited, 50% average particle size: 21 μm, apparent density: 0.6 g/cm³) used was changed from 217.3 parts by mass to 162 parts by mass, the amount of DAP-316L-HTD (stainless steel powder produced by Daido Steel Co., Ltd., 50% average particle size: 10.7 μm, apparent density: 4.1 g/cm³) used was changed from 96.8 parts by mass to 145 parts by mass, and 1 part by mass of 2MAOK (produced by Shikoku Chemicals Corporation, 2,4-diamino-6-[2′-methylimidazolyl-(1′)]-ethyl-s-triazine isocyanuric acid adduct) was used instead of 2MAOK-PW (produced by Shikoku Chemicals Corporation, 2,4-diamino-6-[2′-methylimidazolyl-(1′)]-ethyl-s-triazine isocyanuric acid adduct).

### Example 18

A conductive thermosetting resin composition (Y-18) and a thermosetting reinforcing material (Z-18) that was a conductive adhesive sheet having a thickness of 140 μm were prepared as in Example 9, except that 81 parts by mass of NI-123 (nickel powder produced by Inco Limited, 50% average particle size: 11.7 μm, apparent density: 2.5 g/cm³, roundish) was used instead of DAP-316L-HTD (stainless steel powder produced by Daido Steel Co., Ltd., 50% average particle size: 10.7 μm, apparent density: 4.1 g/cm³), and 1 part by mass of 2MAOK (produced by Shikoku Chemicals Corporation, 2,4-diamino-6-[2′-methylimidazolyl-(1′)]-ethyl-s-triazine isocyanuric acid adduct) was used instead of 2MAOK-PW (produced by Shikoku Chemicals Corporation, 2,4-diamino-6-[2′-methylimidazolyl-(1′)]-ethyl-s-triazine isocyanuric acid adduct).

### Example 19

A conductive thermosetting resin composition (Y-19) and a thermosetting reinforcing material (Z-19) that was a conductive adhesive sheet having a thickness of 140 μm were prepared as in Example 5, except that 108 parts by mass of NI-123 (nickel powder produced by Inco Limited, 50% average particle size: 11.7 μm, apparent density: 2.5 g/cm³) was used instead of DAP-316L-HTD (stainless steel powder produced by Daido Steel Co., Ltd., 50% average particle size: 10.7 μm, apparent density: 4.1 g/cm³), and 1 part by mass of 2MAOK (produced by Shikoku Chemicals Corporation, 2,4-diamino-6-[2′-methylimidazolyl-(1′)]-ethyl-s-triazine isocyanuric acid adduct) was used instead of 2MAOK-PW (produced by Shikoku Chemicals Corporation, 2,4-diamino-6-[2′-methylimidazolyl-(1′)]-ethyl-s-triazine isocyanuric acid adduct).

### Comparative Example 1

A conductive thermosetting resin composition (Y′-1) and a sheet-like conductive thermosetting reinforcing material (Z′-1) having a thickness of 140 μm were prepared as in Example 1, except that 333.3 parts by mass of SG-80H (produced by Nagase ChemteX Corporation, acrylic resin including an epoxy group and an amide group, solid content: 18 mass %) was used instead of the methyl ethyl ketone solution (solid content: 30 mass %) of JER-1256 (produced by Mitsubishi Chemical Corporation, bisphenol-A epoxy resin).

### Comparative Example 2

A conductive thermosetting resin composition (Y′-2) and a sheet-like conductive thermosetting reinforcing material (Z′-2) having a thickness of 140 μm were prepared as in Example 1, except that 400 parts by mass of SG-P3 (produced by Nagase ChemteX Corporation, an acrylic resin including an epoxy group, solid content: 15 mass %) was used instead of the methyl ethyl ketone solution (solid content: 30 mass %) of JER-1256 (produced by Mitsubishi Chemical Corporation, bisphenol-A epoxy resin).

### Comparative Example 3

A conductive thermosetting resin composition (Y′-3) and a sheet-like conductive thermosetting reinforcing material (Z′-3) having a thickness of 140 μm were prepared as in Example 3, except that 150 parts by mass of a toluene-isopropanol solution (solid content: 20 mass %) of TPAE-32 (produced by T&K TOKA, polyether ester amide resin) was used instead of the toluene-isopropanol solution (solid content: 20 mass %) of PA-201 (produced by T&K TOKA, polyether ester amide resin).

### Comparative Example 4

A conductive thermosetting material including a conductive thermal adhesive sheet (CBF-300-W6 produced by Tatsuta Electric Wire Cable Co., LTD, thickness: 60 μm) and a stainless steel sheet (SUS304) having a thickness of 50 μm which was stuck on one surface of the conductive thermal adhesive sheet was used instead of the sheet-like conductive thermosetting reinforcing material according to the present invention.

### Comparative Example 5

A conductive thermosetting material including a conductive thermal adhesive sheet (CBF-300-W6 produced by Tatsuta Electric Wire Cable Co., LTD) and a polyimide film (“KAPTON 500H” produced by DU PONT-TORAY CO., LTD.) having a thickness of 125 μm which was stuck on one surface of the conductive thermal adhesive sheet was used instead of the sheet-like conductive thermosetting reinforcing material according to the present invention.

### Comparative Example 6

A conductive thermosetting resin composition (Y′-4) and a conductive thermosetting reinforcing material (Z′-4) having a thickness of 140 μm were prepared as in Example 4, except that the amount of 830-S (produced by DIC Corporation, bisphenol-F epoxy resin, epoxy equivalent weight: 170 g/eq.) used was changed from 10 parts by mass to 9.5 parts by mass, the amount of methyl ethyl ketone solution (solid content: 80 mass %) of TSR-400 (produced by DIC Corporation, isocyanate-modified bisphenol-A epoxy resin, epoxy equivalent weight: 343 g/eq.) used was changed from 50 parts by mass to 0 part by mass, the amount of methyl ethyl ketone solution (solid content: 30 mass %) of JER-1256 (produced by Mitsubishi Chemical Corporation, bisphenol-A epoxy resin) used was changed from 166.7 parts by mass to 0 part by mass, the amount of 2MAOK-PW (produced by Shikoku Chemicals Corporation, 2,4-diamino-6-[2′-methylimidazolyl-(1′)]-ethyl-s-triazine isocyanuric acid adduct) used was changed from 1 part by mass to 0 part by mass, and 225 parts by mass of UR-3500 (produced by Toyobo Co., Ltd., polyester urethane resin, solid content: 40 mass %) was further used.

### Comparative Example 7

A conductive thermosetting resin composition (Y′-5) and a conductive thermosetting reinforcing material (Z′-5) having a thickness of 140 μm were prepared as in Comparative example 6, except that the amount of 830-S (produced by DIC Corporation, bisphenol-F epoxy resin, epoxy equivalent weight: 170 g/eq.) used was changed from 9.5 parts by mass to 6.7 parts by mass, the amount of UR-3500 (produced by Toyobo Co., Ltd., polyester urethane resin) was changed from 225 parts by mass to 157.5 parts by mass, and 30 parts by mass of BX1001 (produced by Toyobo Co., Ltd., non-crystalline polyester resin) was further used.

### Comparative Example 8

A conductive thermosetting resin composition (Y′-6) and a conductive thermosetting reinforcing material (Z′-6) having a thickness of 140 μm were prepared as in Example 5, except that the amount of 830-S (produced by DIC Corporation, bisphenol-F epoxy resin, epoxy equivalent weight: 170 g/eq.) used was changed from 20 parts by mass to 0 part by mass, the amount of 1055 (produced by DIC Corporation, bisphenol-A epoxy resin, epoxy equivalent weight: 475 g/eq.) used was changed from 30 parts by mass to 24.2 parts by mass, 62.1 parts by mass of BX1001 (produced by Toyobo Co., Ltd., non-crystalline polyester resin) was used instead of the methyl ethyl ketone solution (solid content: 30 mass %) of JER-1256 (produced by Mitsubishi Chemical Corporation, bisphenol-A epoxy resin), and 125.8 parts by mass of UR-1350 (produced by Toyobo Co., Ltd., polyester urethane resin) was further used.

### Comparative Example 9

A conductive thermosetting resin composition (Y′-7) and a thermosetting reinforcing material (Z′-7) that was a conductive adhesive sheet having a thickness of 140 μm were prepared as in Example 1, except that 42.9 parts by mass of a methyl ethyl ketone solution (solid content: 70 mass %) of HP7200 (produced by DIC Corporation, dicyclopentadiene epoxy resin, epoxy equivalent weight: 260 g/eq.) was used instead of the methyl ethyl ketone solution (solid content: 70 mass %) of HP7200HHH (produced by DIC Corporation, dicyclopentadiene epoxy resin, epoxy equivalent weight: 285 g/eq.), the amount of NI-255 (nickel powder produced by Inco Limited, 50% average particle size: 21 μm, apparent density: 0.6 g/cm³) used was changed from 217.3 parts by mass to 324 parts by mass, the amount of DAP-316L-HTD (stainless steel powder produced by Daido Steel Co., Ltd., 50% average particle size: 10.7 μm, apparent density: 4.1 g/cm³) used was changed from 96.8 parts by mass to 0 part by mass, and 10 parts by mass of 830-S (produced by DIC Corporation, bisphenol-F epoxy resin, epoxy equivalent weight: 170 g/eq.) was used instead of 850-S (produced by DIC Corporation, bisphenol-A epoxy resin, epoxy equivalent weight: 188 g/eq.).

### Comparative Example 10

A conductive thermosetting resin composition (Y′-8) and a thermosetting reinforcing material (Z′-8) that was a conductive adhesive sheet having a thickness of 140 μm were prepared as in Example 1, except that 42.9 parts by mass of a methyl ethyl ketone solution (solid content: 70 mass %) of HP7200 (produced by DIC Corporation, dicyclopentadiene epoxy resin, epoxy equivalent weight: 260 g/eq.) was used instead of the methyl ethyl ketone solution (solid content: 70 mass %) of HP7200HHH (produced by DIC Corporation, dicyclopentadiene epoxy resin, epoxy equivalent weight: 285 g/eq.), the amount of NI-255 (nickel powder produced by Inco Limited, 50% average particle size: 21 μm, apparent density: 0.6 g/cm³) used was changed from 217.3 parts by mass to 0 part by mass, NI-255 (nickel powder produced by Inco Limited, 50% average particle size: 21 μm, apparent density: 0.6 g/cm³) the amount of DAP-316L-HTD (stainless steel powder produced by Daido Steel Co., Ltd., 50% average particle size: 10.7 μm, apparent density: 4.1 g/cm³) used was changed from 96.8 parts by mass to 290.3 parts by mass, and 10 parts by mass of 830-S (produced by DIC Corporation, bisphenol-F epoxy resin, epoxy equivalent weight: 170 g/eq.) was used instead of 850-S (produced by DIC Corporation, bisphenol-A epoxy resin, epoxy equivalent weight: 188 g/eq.).

### Comparative Example 11

A conductive thermosetting resin composition (Y′-9) and a thermosetting reinforcing material (Z′-9) that was a conductive adhesive sheet having a thickness of 140 μm were prepared as in Example 17, except that the amount of NI-255 (nickel powder produced by Inco Limited, 50% average particle size: 21 μm, apparent density: 0.6 g/cm³) used was changed from 162 parts by mass to 190 parts by mass, the amount of DAP-316L-HTD (stainless steel powder produced by Daido Steel Co., Ltd., 50% average particle size: 10.7 μm, apparent density: 4.1 g/cm³) used was changed from 145 parts by mass to 0 part by mass, the amount of methyl ethyl ketone solution (solid content: 30 mass %) of JER-1256 (produced by Mitsubishi Chemical Corporation, bisphenol-A epoxy resin) used was changed from 166.7 parts by mass to 200 parts by mass, the amount of methyl ethyl ketone solution (solid content: 80 mass %) of TSR-400 (produced by DIC Corporation, isocyanate-modified bisphenol-A epoxy resin, epoxy equivalent weight: 343 g/eq.) used was changed from 50 parts by mass to 37.5 parts by mass, and 1 part by mass of 2MAOK (produced by Shikoku Chemicals Corporation, 2,4-diamino-6-[2′-methylimidazolyl-(1′)]-ethyl-s-triazine isocyanuric acid adduct) was used instead of 2MAOK-PW (produced by Shikoku Chemicals Corporation, 2,4-diamino-6-[2′-methylimidazolyl-(1′)]-ethyl-s-triazine isocyanuric acid adduct).

### Comparative Example 12

A conductive thermosetting resin composition (Y′-10) and a thermosetting reinforcing material (Z′-10) that was a conductive adhesive sheet having a thickness of 140 μm were prepared as in Example 17, except that the amount of NI-255 (nickel powder produced by Inco Limited, 50% average particle size: 21 μm, apparent density: 0.6 g/cm³) used was changed from 162 parts by mass to 108 parts by mass, the amount of DAP-316L-HTD (stainless steel powder produced by Daido Steel Co., Ltd., 50% average particle size: 10.7 μm, apparent density: 4.1 g/cm³) used was changed from 145 parts by mass to 193.5 parts by mass, and 1 part by mass of 2MAOK (produced by Shikoku Chemicals Corporation, 2,4-diamino-6-[2′-methylimidazolyl-(1′)]-ethyl-s-triazine isocyanuric acid adduct) was used instead of 2MAOK-PW (produced by Shikoku Chemicals Corporation, 2,4-diamino-6-[2′-methylimidazolyl-(1′)]-ethyl-s-triazine isocyanuric acid adduct).

### Comparative Example 13

A conductive thermosetting resin composition (Y′-11) and a thermosetting reinforcing material (Z′-11) that was a conductive adhesive sheet having a thickness of 140 μm were prepared as in Example 5, except that 217.3 parts by mass of NI-123 (nickel powder produced by Inco Limited, 50% average particle size: 11.7 μm, apparent density: 2.5 g/cm³) was used instead of NI-255 (nickel powder produced by Inco Limited, 50% average particle size: 21 μm, apparent density: 0.6 g/cm³).

### Comparative Example 14

A conductive thermosetting resin composition (Y′-12) and a thermosetting reinforcing material (Z′-12) that was a conductive adhesive sheet having a thickness of 140 μm were prepared as in Example 5, except that 337 parts by mass of NI-123 (nickel powder produced by Inco Limited, 50% average particle size: 11.7 μm, apparent density: 2.5 g/cm³) was used instead of NI-255 (nickel powder produced by Inco Limited, 50% average particle size: 21 μm, apparent density: 0.6 g/cm³), the amount of DAP-316L-HTD (stainless steel powder produced by Daido Steel Co., Ltd., 50% average particle size: 10.7 μm, apparent density: 4.1 g/cm³) used was changed from 96.7 parts by mass to 149 parts by mass, and 1 part by mass of 2MAOK (produced by Shikoku Chemicals Corporation, 2,4-diamino-6-[2′-methylimidazolyl-(1′)]-ethyl-s-triazine isocyanuric acid adduct) was used instead of 2MAOK-PW (produced by Shikoku Chemicals Corporation, 2,4-diamino-6-[2′-methylimidazolyl-(1′)]-ethyl-s-triazine isocyanuric acid adduct).

### Comparative Example 15

A conductive thermosetting resin composition (Y′-13) and a thermosetting reinforcing material (Z′-13) that was a conductive adhesive sheet having a thickness of 140 μm were prepared as in Example 5, except that 506 parts by mass of NI-123 (nickel powder produced by Inco Limited, 50% average particle size: 11.7 μm, apparent density: 2.5 g/cm³) was used instead of NI-255 (nickel powder produced by Inco Limited, 50% average particle size: 21 μm, apparent density: 0.6 g/cm³), the amount of DAP-316L-HTD (stainless steel powder produced by Daido Steel Co., Ltd., 50% average particle size: 10.7 μm, apparent density: 4.1 g/cm³) used was changed from 96.7 parts by mass to 223 parts by mass, and 1 part by mass of 2MAOK (produced by Shikoku Chemicals Corporation, 2,4-diamino-6-[2′-methylimidazolyl-(1′)]-ethyl-s-triazine isocyanuric acid adduct) was used instead of 2MAOK-PW (produced by Shikoku Chemicals Corporation, 2,4-diamino-6-[2′-methylimidazolyl-(1′)]-ethyl-s-triazine isocyanuric acid adduct).

### Comparative Example 16

A conductive thermosetting resin composition (Y′-14) and a thermosetting reinforcing material (Z′-14) that was a conductive adhesive sheet having a thickness of 140 μm were prepared as in Example 5, except that the amount of NI-255 (nickel powder produced by Inco Limited, 50% average particle size: 21 μm, apparent density: 0.6 g/cm³) used was changed from 217.3 parts by mass to 108.7 parts by mass, 108.7 parts by mass of NI-123 (nickel powder produced by Inco Limited, 50% average particle size: 11.7 μm, apparent density: 2.5 g/cm³) was further used, and 1 part by mass of 2MAOK (produced by Shikoku Chemicals Corporation, 2,4-diamino-6-[2′-methylimidazolyl-(1′)]-ethyl-s-triazine isocyanuric acid adduct) was used instead of 2MAOK-PW (produced by Shikoku Chemicals Corporation, 2,4-diamino-6-[2′-methylimidazolyl-(1′)]-ethyl-s-triazine isocyanuric acid adduct).

[Method for Measuring Thickness of Conductive Thermosetting Reinforcing Material Cured by Heat]

After the release liner had been removed from the sheet-like conductive thermosetting reinforcing material, the sheet-like conductive thermosetting reinforcing material was cut into a piece having a width of 10 mm and a length of 100 mm. Hereinafter, this piece is referred to as “test piece 1”.

The test piece 1 was interposed between two NITFLON films (PTFE films produced by Nitto Denko Corporation) having a thickness of 0.1 mm and cured at 165° C. for 60 minutes while pressed by a hot pressing apparatus at 2 MPa. Hereby, a test piece 2 (after heat curing) was prepared.

The thickness of the test piece 2 (after heat curing) was measured with a thickness gauge “TH-102” produced by TESTER SANGYO CO., LTD.

### [Method for Measuring Modulus of Tensile Elasticity (×1) and Modulus of Tensile Elasticity (×2) at 25° C.]

The modulus of tensile elasticity (×1) of the test piece 1 (before curing) at 25° C. was measured with a TENSILON tensile testing machine at a test speed of 20 mm/min.

The modulus of tensile elasticity (×2) of the test piece 2 (after heat curing) at 25° C. was measured with a TENSILON tensile testing machine at a test speed of 20 mm/min.

Note that, since the conductive thermosetting reinforcing material prepared in Comparative example 4 included a stainless steel sheet, it was not possible to measure the modulus of tensile elasticity (×1) and modulus of tensile elasticity (×2) of the conductive thermosetting reinforcing material.

### [Method for Measuring Volume Resistance]

A test piece that was the same as the test piece 2 (after heat curing) was prepared and cut into a piece (test piece 3) having dimensions of 50 mm×80 mm. The volume resistance of the test piece 3 was measured with a resistance meter (“Loresta-GP MCP-T600” produced by Mitsubishi Chemical Corporation) by a four-point probe method. In Comparative example 4, the volume resistance of the stainless steel sheet-side surface of the conductive thermosetting reinforcing material was measured by the above method. In Comparative example 5, the volume resistance of the polyimide film-side surface of the conductive thermosetting reinforcing material was measured by the above method.

### [Method for Evaluating Connection Resistance]

A multilayer body (substitute flexible printed circuit board) prepared by sticking an adhesive tape (adhesive tape having dimensions of 20 mm×30 mm×thickness: 15 μm including a polyimide film having a thickness of 25 μm and an adhesive layer disposed on one surface of the polyimide film) having a hole with a diameter of 1 mm formed therein onto the copper surface of a copper foil (20 mm×30 mm×thickness: 36 μm) provided with a gold coating deposited on one surface of the copper foil by electroless plating was used as a substitute for a flexible printed circuit board.

Specific one of the sheet-like conductive thermosetting reinforcing materials prepared in Examples and Comparative examples was stuck onto the surface of the substitute flexible printed circuit board, that is, a surface of the substitute flexible printed circuit board which is opposite to the copper surface plated with gold by electroless plating (this copper surface corresponds to the component surface). A PTFE film (NITFLON produced by Nitto Denko Corporation, registered trademark) was deposited on the conductive thermosetting reinforcing material, and the resulting multilayer body was heated at 165° C. for 60 minutes while pressed by a hot pressing apparatus at 2 MPa in order to cure the thermosetting reinforcing material. Hereby, a reinforced flexible printed circuit board was prepared. The connection resistance of the reinforced flexible printed circuit board, that is, the connection resistance between the gold coating and reinforcing member, was measured with a resistance meter by a two-point probe method.

### [Method for Evaluating Reinforcing Property]

Specific one of the sheet-like conductive thermosetting reinforcing materials prepared in Examples and Comparative examples was interposed between two PTFE films (NITFLON produced by Nitto Denko Corporation) having a thickness of 0.1 mm and cured at 165° C. for 60 minutes while pressed by a hot pressing apparatus at 2 MPa. The resulting cured product was cut into a piece having dimensions of 10 mm×70 mm. This piece was used as a test sample. The test sample was placed on two poles arranged at an interval of 70 mm. The change in the deflection of the test sample at the center of the test sample in the downward direction which occurred when a weight of 0.4 g was loaded at the center of the test sample was measured. Evaluation of reinforcing property was made on the basis of the following criteria.

⊙: The change in deflection of the test sample was 0 mm or more and less than 6 mm

◯: The change in deflection of the test sample was 6 mm or more and less than 8 mm

Δ: The change in deflection of the test sample was 8 mm or more and less than 10 mm

x: The change in deflection of the test sample was 10 mm or more

### [Method for Evaluating Production Efficiency]

A multilayer body (substitute flexible printed circuit board) prepared by sticking an adhesive tape (adhesive tape having dimensions of 20 mm×30 mm×thickness: 15 μm including a polyimide film having a thickness of 25 μm and an adhesive layer disposed on one surface of the polyimide film) having a hole with a diameter of 1 mm formed therein onto the copper surface of a copper foil (20 mm×30 mm×thickness: 36 μm) provided with a gold coating deposited on one surface of the copper foil by electroless plating was used as a substitute for a flexible printed circuit board.

Specific one of the sheet-like conductive thermosetting materials prepared in Examples and Comparative examples was stuck onto the surface of the substitute flexible printed circuit board which is opposite to the copper surface (corresponding to the component surface). The resulting multilayer body was heated at 165° C. for 60 minutes to form a reinforced flexible printed circuit board.

A reinforced flexible printed circuit board produced in two steps (a step in which a conductive thermal adhesive tape is stuck to a stainless steel sheet or the like, and a step in which the resulting assembly is bonded to a flexible printed circuit board) since it included a stainless steel sheet or a polyimide film that has been used as a reinforcing member was evaluated as “x” in terms of production efficiency. A reinforced flexible printed circuit board produced in only one step (a step in which a sheet-like thermosetting material that did not include a stainless steel sheet or the like was stuck to a flexible printed circuit board) was evaluated as “◯” in terms of production efficiency.

### [Method for Evaluating Followability to Stepped Portions]

Specific one of the sheet-like conductive thermosetting reinforcing materials prepared in Examples and Comparative examples was stuck onto the surface of the substitute flexible printed circuit board which is opposite to the copper surface (corresponding to the component surface). A PTFE film (NITFLON produced by Nitto Denko Corporation, registered trademark) was deposited on the conductive thermosetting reinforcing material, and the resulting multilayer body was heated at 165° C. for 60 minutes while pressed by a hot pressing apparatus at 2 MPa in order to cure the thermosetting reinforcing material. Hereby, a reinforced flexible printed circuit board was prepared.

The reinforced flexible printed circuit board was cut in the thickness direction at the hole of the adhesive tape (adhesive tape having dimensions of 20 mm×30 mm×thickness: 40 μm including a polyimide film having a thickness of 25 μm and an adhesive layer disposed on one surface of the polyimide film, the adhesive tape having a hole with a diameter of 1 mm formed therein) included in the reinforced flexible printed circuit board. The cross section of the reinforced flexible printed circuit board was inspected with a scanning electron microscope.

◯: The opening was filled with the conductive thermosetting reinforcing material, and no gap was found

Δ: The opening was not completely filled with the conductive thermosetting reinforcing material, and a few gaps were present

x: The opening was not filled with the conductive thermosetting reinforcing material, and the reinforcing member was detached from the circuit board

### [Method for Evaluating Punching Workability]

After the release liner had been removed from the sheet-like conductive thermosetting reinforcing material, the sheet-like conductive thermosetting reinforcing material was punched into a piece having a width of 10 mm and a length of 100 mm with a punching machine. An evaluation grade of “⊙” was given when the difference between the cut surface and the position at which the blade penetrated the thermosetting reinforcing material was less than 0.1 mm. An evaluation grade of “◯” was given when the difference was 0.1 mm to 0.5 mm or less. An evaluation grade of “Δ” was given when the difference was more than 0.5 mm and 1 mm or less. An evaluation grade of “x” was given when the difference was more than 1 mm.

### [Adhesive Flow]

Three punch holes having a diameter of 6 mm were formed in the conductive adhesive sheet, and the conductive adhesive sheet was interposed between a polyimide film (produced by DU PONT-TORAY CO., LTD., product name: “KAPTON 100H”) having a thickness of 25 μm and a copper foil (glossy surface) having a thickness of 35 μm. The resulting multilayer body was pressed at a temperature of 165° C. and a pressure of 2 MPa for 60 minutes.

After the pressing had been terminated, for each of the punch holes, the maximum distance the adhesive seeped into the inside of the punch hole was measured with an optical microscope. The average of the distances was calculated as “Adhesive flow [mm]”.

In Comparative example 4, where the conductive thermosetting material included a stainless steel sheet, it was not possible to measure adhesive flow.

In Comparative example 5, where the conductive thermosetting material included a polyimide film, it was not possible to measure adhesive flow.

### [Method for Evaluating Adhesive Property]

Specific one of the conductive adhesive sheets prepared in Examples and Comparative examples was cut into a piece having a width of 20 mm and a length of 100 mm. Hereinafter, this piece is referred to as “test piece 3”.

The test piece 3 was interposed between an aluminum plate having a thickness of 1.5 mm and an electrolytic copper foil having a thickness of 35 μm. Subsequently, thermal bonding was performed at 180° C. for 10 minutes with a hot press machine while a pressure of 1 MPa was maintained. Then, the resulting multilayer body was left to stand at 180° C. for 50 minutes in order to cure the test piece 3 by heat. Hereby, a copper foil-laminated multilayer body including an aluminum plate and an electrolytic copper foil that were bonded to each other with the test piece 3 interposed therebetween was prepared.

The copper foil-laminated multilayer plate was left to stand at 23° C. and 50% RH for 1 hour. Under the same conditions, the electrolytic copper foil was removed from the plate in the 180° direction, and the bonding strength (peeling speed: 50 mm/min) of the copper foil was measured.

In Comparative example 4, where the conductive thermosetting material included a stainless steel sheet, an electrolytic copper foil having a thickness of 35 μm was bonded to the conductive thermal adhesive sheet-side surface, and the adhesive property of the copper foil was measured.

In Comparative example 5, where the conductive thermosetting material included a polyimide film, an electrolytic copper foil having a thickness of 35 μm was bonded to the conductive thermal adhesive sheet-side surface, and the adhesive property of the copper foil was measured.

TABLE 1

| | | Example | Example | Example | Example | Example | Example |
|---|---|---|---|---|---|---|---|
| | | 1 | 2 | 3 | 4 | 5 | 6 |
| 850-S [mass part] | | 10.0 | 10.0 | 10.0 | 0.0 | 0.0 | 0.0 |
| 830-S [mass part] | | 0.0 | 0.0 | 0.0 | 10.0 | 20.0 | 20.0 |
| Methyl ethyl ketone solution of HP-7200HHH | | 42.9 | 42.9 | 42.9 | 0.0 | 0.0 | 0.0 |
| (solid content: 70 mass %) [mass part] | | | | | | | |
| Methyl ethyl ketone solution of TSR-400 | | 0.0 | 0.0 | 0.0 | 50.0 | 0.0 | 0.0 |
| (solid content: 80 mass %) [mass part] | | | | | | | |
| 1055 [mass part] | | 0.0 | 0.0 | 0.0 | 0.0 | 30.0 | 30.0 |
| Methyl ethyl ketone solution of EXA-9726 | | 0.0 | 0.0 | 0.0 | 0.0 | 0.0 | 0.0 |
| (solid content: 70 mass %) [mass part] | | | | | | | |
| Methyl ethyl ketone solution of JER-1256 | | 200.0 | 200.0 | 100.0 | 166.7 | 150.0 | 150.0 |
| (solid content: 30 mass %) [mass part] | | | | | | | |
| S-LEC KS-1 [mass part] | | 0.0 | 0.0 | 0.0 | 0.0 | 5.0 | 5.0 |
| SG-80H [mass part] | | 0.0 | 0.0 | 0.0 | 0.0 | 0.0 | 0.0 |
| Toluene/iPA solution of PA-201, solid content: | | 0.0 | 0.0 | 150.0 | 0.0 | 0.0 | 0.0 |
| 20 mass % [mass part] | | | | | | | |
| Curing agent | DICY7 | 0.0 | 2.0 | 0.0 | 0.0 | 0.0 | 0.0 |
| [mass part] | 4,4′-Diaminodiphenylsulfone | 0.0 | 0.0 | 0.0 | 0.0 | 0.0 | 0.0 |
| | 2MAOK-PW | 2.0 | 0.0 | 2.0 | 1.0 | 1.0 | 1.0 |
| | DN-980 | 0.0 | 0.0 | 0.0 | 0.0 | 1.5 | 1.5 |
| Conductive filler | NI-255 | 217.3 | 217.3 | 217.3 | 217.3 | 217.3 | 168.0 |
| [mass part] | NI-123 | 0.0 | 0.0 | 0.0 | 0.0 | 0.0 | 0.0 |
| | DAP-316L-HTD | 96.8 | 96.8 | 96.8 | 96.8 | 96.8 | 75.2 |

| | | | | | | |
|---|---|---|---|---|---|---|
| Proportion of conductive filler to conductive | 30 | 30 | 30 | 30 | 30 | 25 |
| thermosetting material [volume %] | | | | | | |
| Conductive filler (b1)/Conductive filler (b2) | 2/1 | 2/1 | 2/1 | 2/1 | 2/1 | 2/1 |
| [volume ratio] | | | | | | |
| Thickness of conductive thermosetting | 140 | 140 | 140 | 140 | 140 | 140 |
| reinforcing material (before heat curing) [μm] | | | | | | |
| Thickness of conductive thermosetting | 100 | 101 | 99 | 104 | 110 | 108 |
| reinforcing material (after heat curing) [μm] | | | | | | |
| Modulus of tensile elasticity of conductive | 2,440 | 1,830 | 598 | 865 | 1,155 | 1,405 |
| thermosetting reinforcing material (before | | | | | | |
| heat curing) [MPa] | | | | | | |
| Modulus of tensile elasticity of conductive | 4,092 | 5,956 | 3,988 | 6,428 | 4,701 | 4,340 |
| thermosetting reinforcing material (after heat | | | | | | |
| curing) [MPa] | | | | | | |
| Volume resistance [mΩ · cm] | 14.0 | 12.0 | 11.0 | 13.9 | 19.7 | 36.2 |
| Connection resistance [Ω · cm] | 0.14 | 0.12 | 0.14 | 0.08 | 0.09 | 0.39 |
| Reinforcing property | ⊚ | ⊚ | ◯ | ⊚ | ⊚ | ⊚ |
| Production efficiency | ◯ | ◯ | ◯ | ◯ | ◯ | ◯ |
| Followability to stepped portions | ◯ | ◯ | ◯ | ◯ | ◯ | ◯ |

TABLE 2

| | | Example | Example | Example | Example | Example | Example |
|---|---|---|---|---|---|---|---|
| | | 7 | 8 | 9 | 10 | 11 | 12 |
| 850-S [mass part] | | 0.0 | 0.0 | 0.0 | 0.0 | 0.0 | 0.0 |
| 830-S [mass part] | | 20.0 | 20.0 | 20.0 | 20.0 | 20.0 | 20.0 |
| Methyl ethyl ketone solution of HP-7200HHH | | 0.0 | 0.0 | 0.0 | 0.0 | 0.0 | 0.0 |
| (solid content: 70 mass %) [mass part] | | | | | | | |
| Methyl ethyl ketone solution of TSR-400 | | 0.0 | 0.0 | 0.0 | 0.0 | 0.0 | 0.0 |
| (solid content: 80 mass %) [mass part] | | | | | | | |
| 1055 [mass part] | | 30.0 | 30.0 | 30.0 | 30.0 | 30.0 | 30.0 |
| Methyl ethyl ketone solution of EXA-9726 | | 0.0 | 0.0 | 0.0 | 0.0 | 0.0 | 0.0 |
| (solid content: 70 mass %) [mass part] | | | | | | | |
| Methyl ethyl ketone solution of JER-1256 | | 150.0 | 150.0 | 150.0 | 150.0 | 150.0 | 150.0 |
| (solid content: 30 mass %) [mass part] | | | | | | | |
| S-LEC KS-1 [mass part] | | 5.0 | 5.0 | 5.0 | 5.0 | 5.0 | 5.0 |
| SG-80H [mass part] | | 0.0 | 0.0 | 0.0 | 0.0 | 0.0 | 0.0 |
| Toluene/iPA solution of PA-201, solid | | 0.0 | 0.0 | 0.0 | 0.0 | 0.0 | 0.0 |
| content: 20 mass % [mass part] | | | | | | | |
| Curing agent | DICY7 | 0.0 | 0.0 | 0.0 | 0.0 | 0.0 | 0.0 |
| [mass part] | 4,4′-Diaminodiphenylsulfone | 0.0 | 0.0 | 0.0 | 0.0 | 0.0 | 0.0 |
| | 2MAOK-PW | 1.0 | 1.0 | 1.0 | 1.0 | 1.0 | 1.0 |
| | DN-980 | 1.5 | 1.5 | 1.5 | 1.5 | 1.5 | 1.5 |
| Conductive filler | NI-255 | 271.3 | 162.0 | 243.0 | 259.0 | 217.3 | 217.3 |
| [mass part] | NI-123 | 0.0 | 0.0 | 0.0 | 0.0 | 0.0 | 0.0 |
| | DAP-316L-HTD | 121.5 | 145.1 | 72.5 | 58.0 | 96.8 | 96.8 |

| | | | | | | |
|---|---|---|---|---|---|---|
| Proportion of conductive filler to conductive | 35 | 30 | 30 | 30 | 30 | 30 |
| thermosetting material [volume %] | | | | | | |
| Conductive filler (b1)/Conductive filler (b2) | 2/1 | 1/1 | 3/1 | 4/1 | 2/1 | 2/1 |
| [volume ratio] | | | | | | |
| Thickness of conductive thermosetting reinforcing | 140 | 140 | 140 | 140 | 160 | 110 |
| material (before heat curing) [μm] | | | | | | |
| Thickness of conductive thermosetting reinforcing | 105 | 105 | 110 | 114 | 122 | 90 |
| material (after heat curing) [μm] | | | | | | |
| Modulus of tensile elasticity of conductive | 998 | 1,615 | 976 | 1,147 | 1,090 | 1,060 |
| thermosetting reinforcing material (before heat | | | | | | |
| curing) [MPa] | | | | | | |
| Modulus of tensile elasticity of conductive | 4,830 | 5,254 | 3,167 | 5,102 | 4,368 | 4,402 |
| thermosetting reinforcing material (after heat | | | | | | |
| curing) [MPa] | | | | | | |
| Volume resistance [mΩ · cm] | 13.7 | 42.1 | 22.5 | 11.2 | 40.1 | 14.6 |
| Connection resistance [Ω · cm] | 0.14 | 0.36 | 0.06 | 0.03 | 0.09 | 0.08 |
| Reinforcing property | ⊚ | ⊚ | ⊚ | ⊚ | ⊚ | ◯ |
| Production efficiency | ◯ | ◯ | ◯ | ◯ | ◯ | ◯ |
| Followability to stepped portions | ◯ | ◯ | ◯ | ◯ | ◯ | ◯ |

TABLE 3

| | | Example | Example | Example | Example | Example | Example |
|---|---|---|---|---|---|---|---|
| | | 13 | 14 | 15 | 16 | 17 | 18 |
| 830-S [mass part] | | 20.0 | 0.0 | 10.0 | 10.0 | 10.0 | 20.0 |
| Methyl ethyl ketone solution of HP-7200 | | 0.0 | 0.0 | 42.9 | 0.0 | 0.0 | 0.0 |
| (solid content: 70 mass %) [mass part] | | | | | | | |
| Methyl ethyl ketone solution of TSR-400 | | 0.0 | 0.0 | 0.0 | 50.0 | 50.0 | 0.0 |
| (solid content: 80 mass %) [mass part] | | | | | | | |
| 1055 [mass part] | | 30.0 | 0.0 | 0.0 | 0.0 | 0.0 | 30.0 |
| Methyl ethyl ketone solution of EXA-9726 | | 0.0 | 0.0 | 28.6 | 0.0 | 0.0 | 0.0 |
| (solid content: 70 mass %) [mass part] | | | | | | | |
| Methyl ethyl ketone solution of JER-1256 | | 150.0 | 0.0 | 133.3 | 166.7 | 166.7 | 150.0 |
| (solid content: 30 mass %) [mass part] | | | | | | | |
| S-LEC KS-1 [mass part] | | 5.0 | 0.0 | 0.0 | 0.0 | 0.0 | 5.0 |
| Hydrogenated MDI/PTMG prepolymer [mass part] | | 0.0 | 71.6 | 0.0 | 0.0 | 0.0 | 0.0 |
| MBOCA [mass part] | | 0.0 | 28.4 | 0.0 | 0.0 | 0.0 | 0.0 |
| Curing agent | DICY7 | 0 | 0 | 2 | 1.5 | 0 | 0 |
| [mass part] | 4,4′-Diaminodiphenylsulfone | 0 | 0 | 0 | 5.4 | 0 | 0 |
| | 2MAOK-PW | 1.0 | 0.0 | 0.0 | 0.0 | 0.0 | 0.0 |
| | 2MAOK | 0.0 | 0.0 | 0.0 | 0.9 | 1.0 | 1.0 |
| | DN-980 | 1.5 | 0.0 | 0.0 | 0.0 | 0.0 | 1.5 |
| Conductive filler | NI-255 | 217.3 | 217.3 | 217.3 | 217.3 | 162.0 | 243.0 |
| [mass part] | NI-123 | 0.0 | 0.0 | 0.0 | 0.0 | 0.0 | 81.0 |
| | DAP-316L-HTD | 96.8 | 96.8 | 96.8 | 96.8 | 145.0 | |

| | | | | | | |
|---|---|---|---|---|---|---|
| Proportion of conductive filler to conductive | 30 | 30 | 30 | 30 | 30 | 30 |
| thermosetting material [volume %] | | | | | | |
| Conductive filler (b1)/Conductive filler (b2) | 2/1 | 2/1 | 2/1 | 2/1 | 1/1 | 3/1 |
| [volume ratio] | | | | | | |
| Thickness of conductive thermosetting | 90 | 140 | 140 | 140 | 140 | 140 |
| reinforcing material (before heat curing) [μm] | | | | | | |
| Thickness of conductive thermosetting | 79 | 130 | 101 | 110 | 98 | 108 |
| reinforcing material (after heat curing) [μm] | | | | | | |
| Modulus of tensile elasticity of conductive | 1,587 | 1,733 | 1,586 | 738 | 1,183 | 810 |
| thermosetting reinforcing material (before | | | | | | |
| heat curing) [MPa] | | | | | | |
| Modulus of tensile elasticity of conductive | 5,558 | 2,556 | 5,800 | 5,150 | 5,494 | 3,811 |
| thermosetting reinforcing material (after heat | | | | | | |
| curing) [MPa] | | | | | | |
| Volume resistance [mΩ · cm] | 20.2 | 33.9 | 14.6 | 13.5 | 54.7 | 18.4 |
| Connection resistance [Ω · cm] | 0.02 | 0.90 | 0.15 | 0.12 | 0.23 | 0.07 |
| Reinforcing property | Δ | ∘ | ∘ | ∘ | ∘ | ∘ |
| Production efficiency | ∘ | ∘ | ∘ | ∘ | ∘ | ∘ |
| Followability to stepped portions | ∘ | Δ | ∘ | ∘ | ∘ | ∘ |

TABLE 4

| | | Example | Comparative | Comparative | Comparative | Comparative | Comparative |
|---|---|---|---|---|---|---|---|
| | | 19 | example 1 | example 2 | example 3 | example 4 | example 5 |
| 850-S [mass part] | | 0.0 | 10.0 | 10.0 | 10.0 | 0.0 | 0.0 |
| 830-S [mass part] | | 20.0 | 0.0 | 0.0 | 0.0 | 0.0 | 0.0 |
| Methyl ethyl ketone solution of HP- | | 0.0 | 42.9 | 42.9 | 42.9 | 0.0 | 0.0 |
| 7200HHH (solid content: 70 mass %) | | | | | | | |
| [mass part] | | | | | | | |
| Methyl ethyl ketone solution of TSR-400 | | 0.0 | 0.0 | 0.0 | 0.0 | 0.0 | 0.0 |
| (solid content: 80 mass %) [mass part] | | | | | | | |
| 1055 [mass part] | | 30.0 | 0.0 | 0.0 | 0.0 | 0.0 | 0.0 |
| Methyl ethyl ketone solution of JER-1256 | | 150.0 | 0.0 | 0.0 | 100.0 | 0.0 | 0.0 |
| (solid content: 30 mass %) [mass part] | | | | | | | |
| S-LEC KS-1 [mass part] | | 5.0 | 0.0 | 0.0 | 0.0 | 0.0 | 0.0 |
| SG-80H [mass part] | | 0.0 | 333.3 | 0.0 | 0.0 | 0.0 | 0.0 |
| SG-P3 [mass part] | | 0.0 | 0.0 | 400.0 | 0.0 | 0.0 | 0.0 |
| Toluene-isopropanol solution of TPAE-32 | | 0.0 | 0.0 | 0.0 | 150.0 | 0.0 | 0.0 |
| (solid content: 20 mass %) [mass part] | | | | | | | |
| Curing agent | DICY7 | 0.0 | 0.0 | 0.0 | 0.0 | 0.0 | 0.0 |
| [mass part] | 2MAOK-PW | 0.0 | 2.0 | 2.0 | 2.0 | 0.0 | 0.0 |
| | 2MAOK | 1.0 | 0.0 | 0.0 | 0.0 | 0.0 | 0.0 |
| | DN-980 | 1.5 | 0.0 | 0.0 | 0.0 | 0.0 | 0.0 |
| Conductive filler | NI-255 | 217.3 | 217.3 | 217.3 | 217.3 | 0.0 | 0.0 |
| [mass part] | NI-123 | 108.0 | 0.0 | 0.0 | 0.0 | 0.0 | 0.0 |
| | DAP-316L-HTD | 0.0 | 96.8 | 96.8 | 96.8 | 0.0 | 0.0 |

| | | | | | | |
|---|---|---|---|---|---|---|
| Proportion of conductive filler to | 30 | 30 | 30 | 30 | 0.0 | 0.0 |
| conductive thermosetting material | | | | | | |
| [volume %] | | | | | | |
| Conductive filler (b1)/Conductive | 2/1 | 2/1 | 2/1 | 2/1 | 0.0 | 0.0 |
| filler (b2) [volume ratio] | | | | | | |
| Thickness of conductive thermosetting | 140 | 140 | 140 | 140 | 110 | 125 |
| reinforcing material (before heat curing) | | | | | | |
| [μm] | | | | | | |
| Thickness of conductive thermosetting | 100 | 102 | 98 | 106 | 90 | 125 |
| reinforcing material (after heat curing) | | | | | | |
| [μm] | | | | | | |
| Modulus of tensile elasticity of conductive | 1,105 | 56 | 65 | 76 | — | 3,120 |
| thermosetting reinforcing material (before | | | | | | |
| heat curing) [MPa] | | | | | | |
| Modulus of tensile elasticity of conductive | 4,184 | 629 | 696 | 1,795 | — | 3,540 |
| thermosetting reinforcing material (after | | | | | | |
| heat curing) [MPa] | | | | | | |
| Volume resistance [mΩ · cm] | 19.8 | 13.0 | 16.0 | 15.0 | 0.3 | >10⁷ |
| Connection resistance [Ω · cm] | 0.11 | 0.10 | 0.11 | 0.12 | 1.26 | >10⁷ |
| Reinforcing property | ◯ | X | X | X | ⊚ | ◯ |
| Production efficiency | ◯ | ◯ | ◯ | ◯ | X | X |
| Followability to stepped portions | ◯ | ◯ | ◯ | ◯ | X | X |
| Punching workability | ⊚ | ⊚ | ⊚ | ⊚ | Δ | ◯ |
| Adhesive flow [mm] | 0.32 | 0.20 | 0.43 | 0.28 | — | — |

TABLE 5

| | | Comparative | Comparative | Comparative | Comparative | Comparative | Comparative |
|---|---|---|---|---|---|---|---|
| | | example 6 | example 7 | example 8 | example 9 | example 10 | example 11 |
| 850-S [mass part] | | 0.0 | 0.0 | 0.0 | 0.0 | 0.0 | 0.0 |
| 830-S [mass part] | | 9.5 | 6.7 | 0.0 | 10.0 | 10.0 | 10.0 |
| Methyl ethyl ketone solution of HP- | | 0.0 | 0.0 | 0.0 | 42.9 | 42.9 | 0.0 |
| 7200 (solid content: 70 mass %) [mass part] | | | | | | | |
| Methyl ethyl ketone solution of TSR- | | 0.0 | 0.0 | 0.0 | 0.0 | 0.0 | 37.5 |
| 400 (solid content: 80 mass %) [mass part] | | | | | | | |
| 1055 [mass part] | | 0.0 | 0.0 | 24.2 | 0.0 | 0.0 | 0.0 |
| Methyl ethyl ketone solution of JER- | | 0.0 | 0.0 | 0.0 | 200.0 | 200.0 | 200.0 |
| 1256 (solid content: 30 mass %) [mass part] | | | | | | | |
| UR-3500 [mass part] | | 225.0 | 157.5 | 0.0 | 0.0 | 0.0 | 0.0 |
| BX1001 [mass part] | | 0.0 | 30.0 | 62.1 | 0.0 | 0.0 | 0.0 |
| UR-1350 [mass part] | | 0.0 | 0.0 | 125.8 | 0.0 | 0.0 | 0.0 |
| Curing agent | DICY7 | 0.0 | 0.0 | 0.0 | 2.0 | 2.0 | 0.0 |
| [mass part] | 4,4′- | 0.0 | 0.0 | 0.0 | 0.0 | 0.0 | 0.0 |
| | Diaminodiphenylsulfone | | | | | | |
| | 2MAOK-PW | 0.0 | 0.0 | 1.0 | 0.0 | 0.0 | 0.0 |
| | 2MAOK | 0.0 | 0.0 | 0.0 | 0.0 | 0.0 | 1.0 |
| | DN-980 | 0.0 | 0.0 | 1.5 | 0.0 | 0.0 | 0.0 |
| Conductive | NI-255 | 217.3 | 217.3 | 217.3 | 324.0 | 0.0 | 190.0 |
| filler | NI-123 | 0.0 | 0.0 | 0.0 | 0.0 | 0.0 | 0.0 |
| [mass part] | DAP-316L-HTD | 96.8 | 96.8 | 96.8 | 0.0 | 290.3 | 0.0 |

| | | | | | | |
|---|---|---|---|---|---|---|
| Proportion of conductive filler to | 30 | 30 | 30 | 30 | 30 | 20 |
| conductive thermosetting material [volume %] | | | | | | |
| Conductive filler (b1)/Conductive filler | 2/1 | 2/1 | 2/1 | 1/0 | 0/1 | 1/0 |
| (b2) [volume ratio] | | | | | | |
| Thickness of conductive thermosetting | 140 | 140 | 140 | 140 | 140 | 140 |
| reinforcing material (before heat | | | | | | |
| curing) [μm] | | | | | | |
| Thickness of conductive thermosetting | 125 | 112 | 112 | 98 | 78 | 91 |
| reinforcing material (after heat curing) [μm] | | | | | | |
| Modulus of tensile elasticity of | 55 | 53 | 99 | 644 | 10 | 670 |
| conductive thermosetting reinforcing | | | | | | |
| material (before heat curing) [MPa] | | | | | | |
| Modulus of tensile elasticity of | 507 | 244 | 294 | 5,020 | 2,641 | 3,317 |
| conductive thermosetting reinforcing | | | | | | |
| material (after heat curing) [MPa] | | | | | | |
| Volume resistance [mΩ · cm] | 40.9 | 48.9 | 146 | 3.6 | >10,000 | 170 |
| Connection resistance [Ω · cm] | 0.18 | 0.35 | 26.6 | 35.0 | >10,000 | 58 |
| Reinforcing property | x | x | x | ∘ | ∘ | ∘ |
| Production efficiency | ∘ | ∘ | x | ∘ | ∘ | ∘ |
| Followability to stepped portions | Δ | Δ | Δ | Δ | x | ∘ |

TABLE 6

| | | Comparative | Comparative | Comparative | Comparative | Comparative |
|---|---|---|---|---|---|---|
| | | example 12 | example 13 | example 14 | example 15 | example 16 |
| 850-S [mass part] | | 0.0 | 0.0 | 0.0 | 0.0 | 0.0 |
| 830-S [mass part] | | 10.0 | 20.0 | 20.0 | 20.0 | 20.0 |
| Methyl ethyl ketone solution of HP-7200HHH | | 0.0 | 0.0 | 0.0 | 0.0 | 0.0 |
| (solid content: 70 mass %) [mass part] | | | | | | |
| Methyl ethyl ketone solution of TSR-400 (solid | | 50.0 | 0.0 | 0.0 | 0.0 | 0.0 |
| content: 80 mass %) [mass part] | | | | | | |
| 1055 [mass part] | | 0.0 | 30.0 | 30.0 | 30.0 | 30.0 |
| Methyl ethyl ketone solution of EXA-9726 (solid | | 0.0 | 0.0 | 0.0 | 0.0 | 0.0 |
| content: 70 mass %) [mass part] | | | | | | |
| Methyl ethyl ketone solution of JER-1256 (solid | | 166.7 | 150.0 | 150.0 | 150.0 | 150.0 |
| content: 30 mass %) [mass part] | | | | | | |
| S-LEC KS-1 [mass part] | | 0.0 | 5.0 | 5.0 | 5.0 | 5.0 |
| SG-80H [mass part] | | 0.0 | 0.0 | 0.0 | 0.0 | 0.0 |
| SG-P3 [mass part] | | 0.0 | 0.0 | 0.0 | 0.0 | 0.0 |
| Curing agent | DICY7 | 0.0 | 0.0 | 0.0 | 0.0 | 0.0 |
| [mass part] | 4,4′-Diaminodiphenylsulfone | 0.0 | 0.0 | 0.0 | 0.0 | 0.0 |
| | 2MAOK | 1.0 | 1.0 | 1.0 | 1.0 | 1.0 |
| | DN-980 | 0.0 | 1.5 | 1.5 | 1.5 | 1.5 |
| Conductive filler | NI-255 | 108.0 | 0.0 | 0.0 | 0.0 | 108.7 |
| [mass part] | NI-123 | | 217.3 | 337.0 | 506.0 | 108.7 |
| | DAP-316L-HTD | 193.5 | 96.8 | 149.0 | 223.0 | 96.8 |

| | | | | | |
|---|---|---|---|---|---|
| Proportion of conductive filler to conductive | 30 | 30 | 40 | 50 | 30 |
| thermosetting material [volume %] | | | | | |
| Conductive filler (b1)/Conductive filler (b2) | 1/2 | 0/1 | 0/1 | 0/1 | 1/2 |
| [volume ratio] | | | | | |
| Thickness of conductive thermosetting reinforcing | 140 | 140 | 140 | 140 | 140.0 |
| material (before heat curing) [μm] | | | | | |
| Thickness of conductive thermosetting reinforcing | 68 | 80 | 83 | 72 | 68 |
| material (after heat curing) [μm] | | | | | |
| Modulus of tensile elasticity of conductive | 150 | 160 | 216 | 301 | 132 |
| thermosetting reinforcing material (before heat | | | | | |
| curing) [MPa] | | | | | |
| Modulus of tensile elasticity of conductive | 3,691 | 3,809 | 4,213 | 4,358 | 3,912 |
| thermosetting reinforcing material (after heat curing) | | | | | |
| [MPa] | | | | | |
| Volume resistance [mΩ · cm] | 483 | >10,000 | >10,000 | >10,000 | 525 |
| Connection resistance [Ω · cm] | >10,000 | >10,000 | >10,000 | >10,000 | >10,000 |
| Reinforcing property | ◯ | ◯ | Δ | Δ | ⊚ |
| Production efficiency | ◯ | ◯ | ◯ | ◯ | ◯ |
| Followability to stepped portions | ◯ | ◯ | Δ | Δ | ◯ |
| Punching workability | ◯ | ◯ | ◯ | Δ | ◯ |

### Example 15

A thermosetting resin composition (X-15) was prepared by mixing 200 parts by mass of a methyl ethyl ketone solution (solid content: 30 mass %) of JER-1256 (produced by Mitsubishi Chemical Corporation, bisphenol-A epoxy resin, epoxy equivalent weight: 8,000 g/eq.), 10 parts by mass of 850-S (produced by DIC Corporation, bisphenol-A epoxy resin, epoxy equivalent weight: 188 g/eq.), 42.9 parts by mass of a methyl ethyl ketone solution (solid content: 70 mass %) of HP-7200 (produced by DIC Corporation, dicyclopentadiene epoxy resin, epoxy equivalent weight: 285 g/eq.), and 2.0 parts by mass of DICY-7 (produced by Mitsubishi Chemical Corporation, dicyandiamide).

With the thermosetting resin composition (X-15), 217.3 parts by mass of NI-255 (nickel powder produced by Inco Limited, average aspect ratio: more than 3, 50% average particle size: 21 μm, apparent density: 0.6 g/cm³, acicular), that is, acicular conductive filler particles, relative to 100 parts by mass of the solid content of the thermosetting resin composition (X-1) and 96.8 parts by mass of DAP-316L-HTD (stainless steel powder produced by Daido Steel Co., Ltd., average aspect ratio: less than 2, 50% average particle size: 10.7 μm, apparent density: 4.1 g/cm³, roundish), that is, substantially spherical conductive filler particles, were mixed. The resulting mixture was stirred with a dispersion stirrer for 10 minutes to form a conductive thermosetting resin composition (Y-15).

The conductive thermosetting resin composition (Y-15) was applied onto the surface of a release liner (polyethylene terephthalate film having a thickness of 50 μm one surface of which had been made releasable using a silicone compound) with a rod-like metal applicator such that the resulting coating film had a thickness of 140 μm after being dried.

The release liner on which the conductive thermosetting resin composition (Y-15) was deposited was charged in a dryer for 5 minutes at 85° C. and dried. Hereby, a thermosetting reinforcing material (Z-15) that was a conductive adhesive sheet having a thickness of 140 μm was prepared.

### Example 16

A conductive thermosetting resin composition (Y-16) and a thermosetting reinforcing material (Z-16) that was a conductive adhesive sheet having a thickness of 140 μm were prepared as in Example 15, except that 2 parts by mass of 2MA-OK (produced by Shikoku Chemicals Corporation, 2,4-diamino-6-[2′-methylimidazolyl-(1′)]-ethyl-s-triazine isocyanuric acid adduct) was used instead of 2.0 parts by mass of DICY-7 (produced by Mitsubishi Chemical Corporation, dicyandiamide).

### Example 17

A conductive thermosetting resin composition (Y-17) and a thermosetting reinforcing material (Z-17) that was a conductive adhesive sheet having a thickness of 140 μm were prepared as in Example 15, except that the amount of methyl ethyl ketone solution (solid content: 30 mass %) of JER-1256 (produced by Mitsubishi Chemical Corporation, bisphenol-A epoxy resin) used was changed from 200 parts by mass to 133.3 parts by mass, 10 parts by mass of 830-S(bisphenol-F epoxy resin, epoxy equivalent weight: 170 g/eq.) was used instead of 850-S (produced by DIC Corporation, bisphenol-A epoxy resin, epoxy equivalent weight: 188 g/eq.), and 28.6 parts by mass of a methyl ethyl ketone solution (solid content: 70 mass %) of EXA-9726 (produced by DIC Corporation, phosphorus-modified epoxy resin, epoxy equivalent weight: 475 g/eq.) was further used.

### Example 18

A conductive thermosetting resin composition (Y-18) and a thermosetting reinforcing material (Z-18) that was a conductive adhesive sheet having a thickness of 140 μm were prepared as in Example 17, except that the amount of methyl ethyl ketone solution (solid content: 30 mass %) of JER-1256 (produced by Mitsubishi Chemical Corporation, bisphenol-A epoxy resin) used was changed from 133.3 parts by mass to 166.7 parts by mass, 50 parts by mass of a methyl ethyl ketone solution (solid content: 80 mass %) of TSR-400 (produced by DIC Corporation, isocyanate-modified bisphenol-A epoxy resin, epoxy equivalent weight: 343 g/eq.) was used instead of the methyl ethyl ketone solution (solid content: 70 mass %) of EXA-9726 (produced by DIC Corporation, phosphorus-modified epoxy resin, epoxy equivalent weight: 475 g/eq.), the amount of methyl ethyl ketone solution (solid content: 70 mass %) of HP-7200 (produced by DIC Corporation, dicyclopentadiene epoxy resin, epoxy equivalent weight: 285 g/eq.) used was changed from 42.9 parts by mass to 0 part by mass, and 1 part by mass of 2MA-OK (produced by Shikoku Chemicals Corporation, 2,4-diamino-6-[2′-methylimidazolyl-(1′)]-ethyl-s-triazine isocyanuric acid adduct) was used instead of 2.0 parts by mass of DICY-7 (produced by Mitsubishi Chemical Corporation, dicyandiamide).

### Example 19

A conductive thermosetting resin composition (Y-19) and a thermosetting reinforcing material (Z-19) that was a conductive adhesive sheet having a thickness of 140 μm were prepared as in Example 18, except that the amount of 2MA-OK (produced by Shikoku Chemicals Corporation, 2,4-diamino-6-[2′-methylimidazolyl-(1′)]-ethyl-s-triazine isocyanuric acid adduct) used was changed from 1 part by mass to 0.9 parts by mass, and 1.5 parts by mass of DICY-7 (produced by Mitsubishi Chemical Corporation, dicyandiamide) and 5.4 parts by mass of 4,4′-diaminodiphenylsulfone were further used.

### Example 20

A conductive thermosetting resin composition (Y-20) and a thermosetting reinforcing material (Z-20) that was a conductive adhesive sheet having a thickness of 140 μm were prepared as in Example 18, except that the amount of NI-255 (nickel powder produced by Inco Limited, 50% average particle size: 21 μm, apparent density: 0.6 g/cm³, acicular) used was changed from 217.3 parts by mass to 162 parts by mass, and the amount of DAP-316L-HTD (stainless steel powder produced by Daido Steel Co., Ltd., 50% average particle size: 10.7 μm, apparent density: 4.1 g/cm³, roundish) used was changed from 96.8 parts by mass to 145 parts by mass.

### Example 21

A conductive thermosetting resin composition (Y-21) and a thermosetting reinforcing material (Z-21) that was a conductive adhesive sheet having a thickness of 140 μm were prepared as in Example 18, except that the amount of 830-S (produced by DIC Corporation, bisphenol-F epoxy resin, epoxy equivalent weight: 170 g/eq.) used was changed from 10 parts by mass to 20 parts by mass, 30 parts by mass of 1055 (produced by DIC Corporation, bisphenol-A epoxy resin, epoxy equivalent weight: 475 g/eq.) was used instead of TSR-40 (produced by DIC Corporation, isocyanate-modified bisphenol-A epoxy resin, epoxy equivalent weight: 343 g/eq.), the amount of JER-1256 (produced by Mitsubishi Chemical Corporation, bisphenol-A epoxy resin) used was changed from 166.7 parts by mass to 150 parts by mass, and 5 parts by mass of S-LEC KS-1 (produced by SEKISUI CHEMICAL CO., LTD., polyvinyl acetal resin) and 1.5 parts by mass of DN-980 (produced by DIC Corporation, polyisocyanate curing agent) were further used.

### Example 22

A conductive thermosetting resin composition (Y-22) and a thermosetting reinforcing material (Z-22) that was a conductive adhesive sheet having a thickness of 140 μm were prepared as in Example 21, except that the amount of NI-255 (nickel powder produced by Inco Limited, 50% average particle size: 21 μm, apparent density: 0.6 g/cm³, acicular) used was changed from 217.3 parts by mass to 168 parts by mass, and the amount of DAP-316L-HTD (stainless steel powder produced by Daido Steel Co., Ltd., 50% average particle size: 10.7 μm, apparent density: 4.1 g/cm³, roundish) used was changed from 96.8 parts by mass to 75.2 parts by mass.

### Example 23

A conductive thermosetting resin composition (Y-23) and a thermosetting reinforcing material (Z-23) that was a conductive adhesive sheet having a thickness of 140 μm were prepared as in Example 21, except that the amount of NI-255 (nickel powder produced by Inco Limited, 50% average particle size: 21 μm, apparent density: 0.6 g/cm³, acicular) used was changed from 217.3 parts by mass to 271.3 parts by mass, and the amount of DAP-316L-HTD (stainless steel powder produced by Daido Steel Co., Ltd., 50% average particle size: 10.7 μm, apparent density: 4.1 g/cm³, roundish) used was changed from 96.8 parts by mass to 121.5 parts by mass.

### Example 24

A conductive thermosetting resin composition (Y-24) and a thermosetting reinforcing material (Z-24) that was a conductive adhesive sheet having a thickness of 140 μm were prepared as in Example 21, except that the amount of NI-255 (nickel powder produced by Inco Limited, 50% average particle size: 21 μm, apparent density: 0.6 g/cm³, acicular) used was changed from 217.3 parts by mass to 162 parts by mass, and the amount of DAP-316L-HTD (stainless steel powder produced by Daido Steel Co., Ltd., 50% average particle size: 10.7 μm, apparent density: 4.1 g/cm³, roundish) used was changed from 96.8 parts by mass to 145.1 parts by mass.

### Example 25

A conductive thermosetting resin composition (Y-25) and a thermosetting reinforcing material (Z-25) that was a conductive adhesive sheet having a thickness of 140 μm were prepared as in Example 21, except that the amount of NI-255 (nickel powder produced by Inco Limited, 50% average particle size: 21 μm, apparent density: 0.6 g/cm³, acicular) used was changed from 217.3 parts by mass to 243 parts by mass, and the amount of DAP-316L-HTD (stainless steel powder produced by Daido Steel Co., Ltd., 50% average particle size: 10.7 μm, apparent density: 4.1 g/cm³, roundish) used was changed from 96.8 parts by mass to 72.5 parts by mass.

### Example 26

A conductive thermosetting resin composition (Y-26) and a thermosetting reinforcing material (Z-26) that was a conductive adhesive sheet having a thickness of 140 μm were prepared as in Example 25, except that 81 parts by mass of NI-123 (nickel powder produced by Inco Limited, 50% average particle size: 11.7 μm, apparent density: 2.5 g/cm³, roundish) was used instead of DAP-316L-HTD (stainless steel powder produced by Daido Steel Co., Ltd., 50% average particle size: 10.7 μm, apparent density: 4.1 g/cm³, roundish).

### Example 27

A conductive thermosetting resin composition (Y-27) and a thermosetting reinforcing material (Z-27) that was a conductive adhesive sheet having a thickness of 140 μm were prepared as in Example 21, except that 108 parts by mass of NI-123 (nickel powder produced by Inco Limited, 50% average particle size: 11.7 μm, apparent density: 2.5 g/cm³, roundish) was used instead of DAP-316L-HTD (stainless steel powder produced by Daido Steel Co., Ltd., 50% average particle size: 10.7 μm, apparent density: 4.1 g/cm³, roundish).

### Example 28

A thermosetting reinforcing material (Z-28) that was a conductive adhesive sheet was prepared as in Example 21, except that the thickness of the conductive adhesive sheet was changed from 140 μm to 160 μm.

### Example 29

A thermosetting reinforcing material (Z-29) that was a conductive adhesive sheet was prepared as in Example 21, except that the thickness of the conductive adhesive sheet was changed from 140 μm to 110 μm.

### Example 30

A thermosetting reinforcing material (Z-30) that was a conductive adhesive sheet was prepared as in Example 21, except that the thickness of the conductive adhesive sheet was changed from 140 μm to 90 μm.

### Example 31

A conductive thermosetting resin composition (Z-31) and a thermosetting reinforcing material (Z-31) that was a conductive adhesive sheet having a thickness of 140 μm were prepared as in Example 21, except that the amount of NI-255 (nickel powder produced by Inco Limited, 50% average particle size: 21 μm, apparent density: 0.6 g/cm³, acicular) used was changed from 217.3 parts by mass to 259 parts by mass, and the amount of DAP-316L-HTD (stainless steel powder produced by Daido Steel Co., Ltd., 50% average particle size: 10.7 μm, apparent density: 4.1 g/cm³, roundish) used was changed from 96.8 parts by mass to 58 parts by mass.

### Comparative Example 9

A conductive thermosetting resin composition (Y′-9) and a thermosetting reinforcing material (Z′-9) that was a conductive adhesive sheet having a thickness of 140 μm were prepared as in Example 15, except that the amount of NI-255 (nickel powder produced by Inco Limited) used was changed from 217.3 parts by mass to 324 parts by mass, the amount of DAP-316L-HTD (stainless steel powder produced by Daido Steel Co., Ltd.) used was changed from 96.8 parts by mass to 0 part by mass, and 10 parts by mass of 830-S (produced by DIC Corporation, bisphenol-F epoxy resin, epoxy equivalent weight: 170 g/eq.) was used instead of 850-S (produced by DIC Corporation, bisphenol-A epoxy resin, epoxy equivalent weight: 188 g/eq.).

### Comparative Example 10

A conductive thermosetting resin composition (Y′-10) and a thermosetting reinforcing material (Z′-10) that was a conductive adhesive sheet having a thickness of 140 μm were prepared as in Example 15, except that the amount of NI-255 (nickel powder produced by Inco Limited) used was changed from 217.3 parts by mass to 0 part by mass, the amount of DAP-316L-HTD (stainless steel powder produced by Daido Steel Co., Ltd.) used was changed from 96.8 parts by mass to 290.3 parts by mass, and 10 parts by mass of 830-S (produced by DIC Corporation, bisphenol-F epoxy resin, epoxy equivalent weight: 170 g/eq.) was used instead of 850-S (produced by DIC Corporation, bisphenol-A epoxy resin, epoxy equivalent weight: 188 g/eq.).

### Comparative Example 11

A conductive thermosetting resin composition (Y′-11) and a thermosetting reinforcing material (Z′-11) that was a conductive adhesive sheet having a thickness of 140 μm were prepared as in Example 20, except that the amount of NI-255 (nickel powder produced by Inco Limited) used was changed from 162 parts by mass to 190 parts by mass, the amount of DAP-316L-HTD (stainless steel powder produced by Daido Steel Co., Ltd.) used was changed from 145 parts by mass to 0 part by mass, the amount of methyl ethyl ketone solution (solid content: 30 mass %) of JER-1256 (produced by Mitsubishi Chemical Corporation, bisphenol-A epoxy resin) used was changed from 166.7 parts by mass to 200 parts by mass, and the amount of methyl ethyl ketone solution (solid content: 80 mass %) of TSR-400 (produced by DIC Corporation, isocyanate modified bisphenol-A epoxy resin, epoxy equivalent weight: 343 g/eq.) used was changed from 50 parts by mass to 37.5 parts by mass.

### Comparative Example 12

A conductive thermosetting resin composition (Y′-12) and a thermosetting reinforcing material (Z′-12) that was a conductive adhesive sheet having a thickness of 140 μm were prepared as in Example 20, except that the amount of NI-255 (nickel powder produced by Inco Limited) used was changed from 162 parts by mass to 108 parts by mass, and the amount of DAP-316L-HTD (stainless steel powder produced by Daido Steel Co., Ltd.) used was changed from 145 parts by mass to 193.5 parts by mass.

### Comparative Example 13

A conductive thermosetting resin composition (Y′-13) and a thermosetting reinforcing material (Z′-13) that was a conductive adhesive sheet having a thickness of 140 μm were prepared as in Example 21, except that 217.3 parts by mass of NI-123 (nickel powder produced by Inco Limited, 50% average particle size: 11.7 μm, apparent density: 2.5 g/cm³, roundish) was used instead of NI-255 (nickel powder produced by Inco Limited, 50% average particle size: 21 μm, apparent density: 0.6 g/cm³, acicular).

### Comparative Example 14

A conductive thermosetting resin composition (Y′-14) and a thermosetting reinforcing material (Z′-14) that was a conductive adhesive sheet having a thickness of 140 μm were prepared as in Comparative example 13, except that the amount of NI-123 (produced by Daido Steel Co., Ltd., stainless steel powder, 50% average particle size: 10.7 μm, apparent density: 4.1 g/cm³, roundish) used was changed from 217.3 parts by mass to 337 parts by mass, and the amount of DAP-316L-HTD (stainless steel powder produced by Daido Steel Co., Ltd., 50% average particle size: 10.7 μm, apparent density: 4.1 g/cm³, roundish) used was changed from 96.8 parts by mass to 149 parts by mass.

### Comparative Example 15

A conductive thermosetting resin composition (Y′-15) and a thermosetting reinforcing material (Z′-15) that was a conductive adhesive sheet having a thickness of 140 μm were prepared as in Comparative example 13, except that the amount of NI-123 (nickel powder produced by Inco Limited, 50% average particle size: 11.7 μm, apparent density: 2.5 g/cm³, roundish) used was changed from 217.3 parts by mass to 506 parts by mass, and the amount of DAP-316L-HTD (stainless steel powder produced by Daido Steel Co., Ltd., 50% average particle size: 10.7 μm, apparent density: 4.1 g/cm³, roundish) used was changed from 96.8 parts by mass to 223 parts by mass.

### Comparative Example 16

A conductive thermosetting resin composition (Y′-16) and a thermosetting reinforcing material (Z′-16) that was a conductive adhesive sheet having a thickness of 140 μm were prepared as in Example 21, except that the amount of NI-255 (nickel powder produced by Inco Limited, 50% average particle size: 21 μm, apparent density: 0.6 g/cm³, acicular) used was changed from 217.3 parts by mass to 108.7 parts by mass, and 108.7 parts by mass of NI-123 (nickel powder produced by Inco Limited, 50% average particle size: 11.7 μm, apparent density: 2.5 g/cm³, roundish) was further used.

### [Adhesive Flow]

Three punch holes having a diameter of 6 mm were formed in the conductive adhesive sheet, and the conductive adhesive sheet was interposed between a polyimide film (produced by DU PONT-TORAY CO., LTD., product name: “KAPTON 100H”) having a thickness of 25 μm and a copper foil (glossy surface) having a thickness of 35 μm. The resulting multilayer body was pressed at a temperature of 165° C. and a pressure of 2 MPa for 60 minutes.

After the pressing had been terminated, for each of the punch holes, the maximum distance the adhesive seeped into the inside of the punch hole was measured with an optical microscope. The average of the distances was calculated as “Adhesive flow [mm]”.

### [Method for Measuring Volume Resistance]

A test piece that was the same as the test piece 2 (after heat curing) was prepared and cut into a piece (test piece 3) having dimensions of 50 mm×80 mm. The volume resistance of the test piece 3 was measured with a resistance meter (“Loresta-GP MCP-T600” produced by Mitsubishi Chemical Corporation) by a four-point probe method.

### [Method for Evaluating Adhesive Property]

Specific one of the conductive adhesive sheets prepared in Examples and Comparative examples was cut into a piece having a width of 20 mm and a length of 100 mm. Hereinafter, this piece is referred to as “test piece 3”.

The test piece 3 was interposed between an aluminum plate having a thickness of 1.5 mm and an electrolytic copper foil having a thickness of 35 μm. Subsequently, thermal bonding was performed at 180° C. for 10 minutes with a hot press machine while a pressure of 1 MPa was maintained. Then, the resulting multilayer body was left to stand at 180° C. for 50 minutes in order to cure the test piece 3 by heat. Hereby, a copper foil-laminated multilayer body including an aluminum plate and an electrolytic copper foil that were bonded to each other with the test piece 3 interposed therebetween was prepared.

The copper foil-laminated multilayer plate was left to stand at 23° C. and 50% RH for 1 hour. Under the same conditions, the electrolytic copper foil was removed from the plate in the 180° direction, and the bonding strength (peeling speed: 50 mm/min) of the copper foil was measured.

TABLE 7

| | | Example | Example | Example | Example | Example | Example | Example |
|---|---|---|---|---|---|---|---|---|
| | | 15 | 16 | 17 | 18 | 19 | 20 | 21 |
| 850-S [mass part] | | 10.0 | 10.0 | | | | | |
| 830-S [mass part] | | | | 10.0 | 10.0 | 10.0 | 10.0 | 20.0 |
| JER604 [mass part] | | | | | | | | |
| Methyl ethyl ketone solution of HP-7200 (solid | | 42.9 | 42.9 | 42.9 | | | | |
| content: 70 mass %) [mass part] | | | | | | | | |
| 1055 [mass part] | | | | | | | | 30.0 |
| Methyl ethyl ketone solution of TSR-400 (solid | | | | | 50.0 | 50.0 | 50.0 | |
| content: 80 mass %) [mass part] | | | | | | | | |
| Methyl ethyl ketone solution of EXA-9726 (solid | | | | 28.6 | | | | |
| content: 70 mass %) [mass part] | | | | | | | | |
| Methyl ethyl ketone solution of JER-1256 (solid | | 200.0 | 200.0 | 133.3 | 166.7 | 166.7 | 166.7 | 150.0 |
| content: 30 mass %) [mass part] | | | | | | | | |
| S-LEC KS-1 [mass part] | | | | | | | | 5.0 |
| Curing agent | DICY-7 | 2.0 | | 2.0 | | 1.5 | | |
| [mass part] | 4,4′-Diaminodiphenylsulfone | | | | | 5.4 | | |
| | 2MA-OK | | 2.0 | | 1.0 | 0.9 | 1.0 | 1.0 |
| | DN-980 | | | | | | | 1.5 |
| Conductive filler | NI-255 | 217.3 | 217.3 | 217.3 | 217.3 | 217.3 | 162.0 | 217.3 |
| [mass part] | NI-123 | | | | | | | |
| | DAP-316L-HTD | 96.8 | 96.8 | 96.8 | 96.8 | 96.8 | 145.0 | 96.8 |

| | | | | | | | |
|---|---|---|---|---|---|---|---|
| Proportion of conductive filler to conductive | 30 | 30 | 30 | 30 | 30 | 30 | 30 |
| adhesive sheet [volume %] | | | | | | | |
| Conductive filler (b1)/Conductive filler (b2) | 2/1 | 2/1 | 2/1 | 2/1 | 2/1 | 1/1 | 2/1 |
| [volume ratio] | | | | | | | |
| Thickness of conductive adhesive sheet | 140 | 140 | 140 | 140 | 140 | 140 | 140 |
| (before heat curing) [μm] | | | | | | | |
| Thickness of conductive adhesive sheet | 101 | 99 | 101 | 104 | 110 | 98 | 110 |
| (after heat curing) [μm] | | | | | | | |
| Modulus of tensile elasticity of conductive | 1,830 | 2,440 | 1,585 | 865 | 738 | 1,183 | 1,155 |
| adhesive sheet (before heat curing) [MPa] | | | | | | | |
| Modulus of tensile elasticity of conductive | 5,956 | 4,092 | 5,802 | 6,428 | 5,150 | 5,494 | 4,702 |
| adhesive sheet (after heat curing) [MPa] | | | | | | | |
| Adhesive flow [mm] | 0.10 | 0.05 | 0.42 | 0.43 | 0.95 | 0.90 | 0.06 |
| Bonding strength [N/cm] | 7.0 | 6.5 | 9.4 | 10.1 | 10.5 | 10.5 | 13.5 |
| Volume resistance [mΩ · cm] | 12.0 | 14.0 | 14.6 | 13.9 | 13.5 | 54.7 | 19.7 |

TABLE 8

| | | Example | Example | Example | Example | Example | Example |
|---|---|---|---|---|---|---|---|
| | | 22 | 23 | 24 | 25 | 26 | 27 |
| 830-S [mass part] | | 20.0 | 20.0 | 20.0 | 20.0 | 20.0 | 20.0 |
| 1055 [mass part] | | 30.0 | 30.0 | 30.0 | 30.0 | 30.0 | 30.0 |
| Methyl ethyl ketone solution of JER-1256 | | 150.0 | 150.0 | 150.0 | 150.0 | 150.0 | 150.0 |
| (solid content: 30 mass %) [mass part] | | | | | | | |
| S-LEC KS-1 [mass part] | | 5.0 | 5.0 | 5.0 | 5.0 | 5.0 | 5.0 |
| Curing agent | DICY-7 | | | | | | |
| [mass part] | 4,4′-Diaminodiphenylsulfone | | | | | | |
| | 2MA-OK | 1.0 | 1.0 | 1.0 | 1.0 | 1.0 | 1.0 |
| | DN-980 | 1.5 | 1.5 | 1.5 | 1.5 | 1.5 | 1.5 |
| Conductive filler | NI-255 | 168.0 | 271.3 | 162.0 | 243.0 | 243.0 | 217.3 |
| [mass part] | NI-123 | | | | | 81.0 | 108.0 |
| | DAP-316L-HTD | 75.2 | 121.5 | 145.1 | 72.5 | | |

| | | | | | | |
|---|---|---|---|---|---|---|
| Proportion of conductive filler to | 25 | 35 | 30 | 30 | 30 | 30 |
| conductive adhesive sheet [volume %] | | | | | | |
| Conductive filler (b1)/Conductive filler | 2/1 | 2/1 | 1/1 | 3/1 | 3/1 | 2/1 |
| (b2) [volume ratio] | | | | | | |
| Thickness of conductive adhesive sheet | 140 | 140 | 140 | 140 | 140 | 140 |
| (before heat curing) [μm] | | | | | | |
| Thickness of conductive adhesive sheet | 108 | 105 | 105 | 110 | 108 | 100 |
| (after heat curing) [μm] | | | | | | |
| Modulus of tensile elasticity of conductive | 1,406 | 998 | 1,615 | 976 | 810 | 1,105 |
| adhesive sheet (before heat curing) [MPa] | | | | | | |
| Modulus of tensile elasticity of conductive | 4,340 | 4,830 | 5,254 | 3,667 | 3,811 | 4,184 |
| adhesive sheet (after heat curing) [MPa] | | | | | | |
| Adhesive flow [mm] | 0.32 | 0.05 | 0.30 | 0.05 | 0.06 | 0.32 |
| Bonding strength [N/cm] | 14.0 | 8.0 | 9.5 | 14.5 | 13.2 | 14.3 |
| Volume resistance [mΩ · cm] | 36.2 | 13.7 | 42.1 | 22.5 | 18.4 | 19.8 |

TABLE 9

| | | Example | Example | Example | Example | Comparative | Comparative |
|---|---|---|---|---|---|---|---|
| | | 28 | 29 | 30 | 31 | example 9 | example 10 |
| 830-S [mass part] | | 20.0 | 20.0 | 20.0 | 20.0 | 10.0 | 10.0 |
| Methyl ethyl ketone solution of HP-7200 (solid | | | | | | 30.0 | 30.0 |
| content: 70 mass %) [mass part] | | | | | | | |
| 1055 [mass part] | | 30.0 | 30.0 | 30.0 | 30.0 | | |
| Methyl ethyl ketone solution of JER-1256 (solid | | 150.0 | 150.0 | 150.0 | 150.0 | 60.0 | 60.0 |
| content: 30 mass %) [mass part] | | | | | | | |
| S-LEC KS-1 [mass part] | | 5.0 | 5.0 | 5.0 | 5.0 | | |
| Curing agent | DICY-7 | | | | | 2.0 | 2.0 |
| [mass part] | 4,4′-Diaminodiphenylsulfone | | | | | | |
| | 2MA-OK | 1.0 | 1.0 | 1.0 | 1.0 | | |
| | DN-980 | 1.5 | 1.5 | 1.5 | 1.5 | | |
| Conductive filler | NI-255 | 217.3 | 217.3 | 217.3 | 259.0 | 324.0 | |
| [mass part] | NI-123 | | | | | | |
| | DAP-316L-HTD | 121.5 | 121.5 | 121.5 | 58.0 | | 290.3 |

| | | | | | | |
|---|---|---|---|---|---|---|
| Proportion of conductive filler to conductive adhesive | 30 | 30 | 30 | 30 | 30 | 30 |
| sheet [volume %] | | | | | | |
| Conductive filler (b1)/Conductive filler (b2) | 2/1 | 2/1 | 2/1 | 4/1 | 1/0 | 0/1 |
| [volume ratio] | | | | | | |
| Thickness of conductive adhesive sheet (before heat | 160 | 110 | 90 | 140.0 | 140 | 140 |
| curing) [μm] | | | | | | |
| Thickness of conductive adhesive sheet (after heat | 122 | 91 | 79 | 114 | 98 | 78 |
| curing) [μm] | | | | | | |
| Modulus of tensile elasticity of conductive adhesive | 1,090 | 1,061 | 1,587 | 1,147 | 644 | 10 |
| sheet (before heat curing) [MPa] | | | | | | |
| Modulus of tensile elasticity of conductive adhesive | 4,606 | 4,403 | 5,558 | 5,102 | 5,020 | 2,641 |
| sheet (after heat curing) [MPa] | | | | | | |
| Adhesive flow [mm] | 0.06 | 0.06 | 0.04 | 0.06 | 0.03 | >3.0 |
| Bonding strength [N/cm] | 11.5 | 13.2 | 7.8 | 6.6 | 4.5 | 9.0 |
| Volume resistance [mΩ · cm] | 40.1 | 14.6 | 20.2 | 11.2 | 3.6 | >10,000 |

TABLE 10

| | | Comparative | Comparative | Comparative | Comparative | Comparative | Comparative |
|---|---|---|---|---|---|---|---|
| | | example 11 | example 12 | example 13 | example 14 | example 15 | example 16 |
| 830-S [mass part] | | 10.0 | 10.0 | 20.0 | 20.0 | 20.0 | 20.0 |
| 1055 [mass part] | | | | 30.0 | 30.0 | 30.0 | 30.0 |
| Methyl ethyl ketone solution of TSR- | | 37.5 | 50.0 | | | | |
| 400 (solid content: 80 mass %) | | | | | | | |
| [mass part] | | | | | | | |
| Methyl ethyl ketone solution of JER- | | 200.0 | 166.7 | 150.0 | 150.0 | 150.0 | 150.0 |
| 1256 (solid content: 30 mass %) | | | | | | | |
| [mass part] | | | | | | | |
| S-LEC KS-1 [mass part] | | | | 5.0 | 5.0 | 5.0 | 5.0 |
| Curing agent | DICY7 | | | | | | |
| [mass part] | 4,4′-Diaminodiphenylsulfone | | | | | | |
| | 2MA-OK | 1.0 | 1.0 | 1.0 | 1.0 | 1.0 | 1.0 |
| | DN-980 | | | 1.5 | 1.5 | 1.5 | 1.5 |
| Conductive | NI-255 | 190.0 | 108.0 | | | | 108.7 |
| filler | NI-123 | | | 217.3 | 337.0 | 506.0 | 108.7 |
| [mass part] | DAP-316L-HTD | 0.0 | 193.5 | 96.8 | 149.0 | 223.0 | 96.8 |

| | | | | | | |
|---|---|---|---|---|---|---|
| Proportion of conductive filler to | 20 | 30 | 30 | 40 | 50 | 30 |
| conductive adhesive sheet [volume %] | | | | | | |
| Conductive filler (b1)/Conductive filler | 1/0 | 1/2 | 0/1 | 0/1 | 0/1 | 1/2 |
| (b2) [volume ratio] | | | | | | |
| Thickness of conductive adhesive | 140 | 140 | 140 | 140 | 140 | 140.0 |
| sheet (before heat curing) [μm] | | | | | | |
| Thickness of conductive adhesive | 91 | 68 | 80 | 83 | 72 | 68 |
| sheet (after heat curing) [μm] | | | | | | |
| Modulus of tensile elasticity of | 670 | 150 | 160 | 216 | 301 | 132 |
| conductive adhesive sheet (before | | | | | | |
| heat curing) [MPa] | | | | | | |
| Modulus of tensile elasticity of | 3,317 | 3,691 | 3,809 | | | 3,912 |
| conductive adhesive sheet (after heat | | | | | | |
| curing) [MPa] | | | | | | |
| Adhesive flow [mm] | 1.12 | >3.0 | >3.0 | >3.0 | >3.0 | >3.0 |
| Bonding strength [N/cm] | 8.0 | 7.5 | 4.3 | 4.0 | 4.5 | 3.2 |
| Volume resistance [mΩ · cm] | 170 | 483 | >10,000 | >10,000 | >10,000 | 525 |

1. A thermosetting material used for reinforcing a flexible printed circuit board, the thermosetting material having a modulus of tensile elasticity (×1) of 50 to 2,500 MPa at 25° C., a heat-cured product of the thermosetting material having a modulus of tensile elasticity (×2) of 2,500 MPa or more at 25° C.

2. The thermosetting material used for reinforcing a flexible printed circuit board according to claim 1, wherein the modulus of tensile elasticity (×2) of the heat-cured product of the thermosetting material at 25° C. is 3,000 MPa or more.

3. The thermosetting material according to claim 1, having a thickness of 50 to 350 μm.

4. The thermosetting material according to claim 1, having a volume resistance of 0.1 to 50 mΩ·cm.

5. The thermosetting material according to claim 1, including a thermosetting resin and a conductive filler (B).

6. The thermosetting material according to claim 5, wherein the thermosetting resin includes the compound (A) including two or more epoxy groups, the conductive filler (B) includes acicular or scale-like conductive filler particles (b1) and substantially spherical conductive filler particles (b2), and wherein the volume ratio [(b1)/(b2)] of the acicular or scale-like conductive filler particles (b1) to the substantially spherical conductive filler particles (b2) is 1/1 to 4/1.

7. The thermosetting material according to claim 6, wherein the compound (A) includes an epoxy resin (a1) and an epoxy resin (a2), the epoxy resin (a1) being liquid at 23° C. and having an epoxy equivalent weight of 100 to 350 g/eq., the epoxy resin (a2) being solid at 23° C. and having an epoxy equivalent weight of 200 to 2,000 g/eq.

8. The thermosetting material according to claim 6, wherein the ratio of the volume of the conductive filler (B) to the total volume of the compound (A) and the conductive filler (B) is 10% to 50% by volume.

9. A reinforced flexible printed circuit board including a flexible printed circuit board and a reinforcing member disposed on the flexible printed circuit board, the reinforcing member having a modulus of tensile elasticity (×3) of 2,500 MPa or more at 25° C., the reinforcing member being a heat-cured product of the thermosetting material according to claim 1.

10. A method for producing a reinforced flexible printed circuit board, the method comprising a step [1] in which the thermosetting material according to claim 1 is stuck or applied to a surface of a flexible printed circuit board which is on a side opposite to a component side of the flexible printed circuit board, and a step [2] in which the thermosetting material is heated to 120° C. or more so as to be cured by heat to form a reinforcing member having a modulus of tensile elasticity (×3) of 2,500 MPa or more at 25° C.

11. An electronic device comprising a reinforced flexible printed circuit board including a flexible printed circuit board and a reinforcing member disposed on the flexible printed circuit board, and a cushioning material disposed on a surface of the reinforcing member directly or with another layer interposed between the cushioning material and the reinforcing member, the reinforcing member having a modulus of tensile elasticity (×3) of 2,500 MPa or more at 25° C., the reinforcing member being a heat-cured product of the thermosetting material according to claim 1.
